(19) United States
(12) Patent Application Publication
(10) Pub. No.: US 2025/0167790 A1
(43) Pub. Date: May 22, 2025

(54) APPARATUS AND METHOD FOR GENERATING CLOCK TO INCREASE POWER EFFICIENCY

(71) Applicant: SAMSUNG ELECTRONICS CO., LTD., Suwon-si (KR)

(72) Inventors: Yongsun Lee, Suwon-si (KR); Suneui Park, Suwon-si (KR); Jaewoo Park, Suwon-si (KR); Jinook Jung, Suwon-si (KR); Myoungbo Kwak, Suwon-si (KR)

(21) Appl. No.: 18/889,081

(22) Filed: Sep. 18, 2024

(30) Foreign Application Priority Data
Nov. 16, 2023 (KR) 10-2023-0159217

(51) Int. Cl. H03L 7/099; H03L 7/093; H03L 7/18

(52) U.S. Cl. CPC H03L 7/099; H03L 7/093; H03L 7/18

(57) ABSTRACT

An example apparatus for generating a clock includes a phase locked loop circuit to generate a first clock signal having a specified frequency through an oscillator, a monitoring circuit to monitor a first bit error rate (BER) of a first signal received in response to the first clock signal, and a control logic circuit to control the phase locked loop circuit based on a monitoring result. The control logic circuit is to connect a first boosting current source, which is included in the phase locked loop circuit, with the oscillator, when the first bit error rate is equal to or greater than a preset threshold value, and disconnect a second boosting current source, which is previously connected with the oscillator, from the oscillator, when the first bit error rate is less than the threshold value.

### CROSS-REFERENCE TO RELATED APPLICATION

This application claims priority under 35 U.S.C. § 119 to Korean Patent Application No. 10-2023-0159217 filed on Nov. 16, 2023, in the Korean Intellectual Property Office, the disclosures of which are incorporated by reference herein in their entireties.

### BACKGROUND

A phase locked loop (PLL) circuit and a clock generating device including the phase locked loop circuit may generate a clock signal having a phase locked. For example, the clock signal may be used to transmit data in a transmitter or to restore data in a receiver. In this case, the phase locked loop circuit may be divided into a ring-PLL circuit, and an inductor-capacitor (LC)-PLL circuit.

Recently, to improve the noise characteristics of the phase locked loop circuit, a technology for controlling the strength of the power used in the operation of the phase locked loop circuit has been studied.

For example, using a required amount of power when a signal received through the receiver has the highest noise characteristics, a manner of controlling the operation of the phase locked loop circuit is employed.

However, in this case, even if the noise characteristics of the signal received through the receiver is changed, the power efficiency of the operation for controlling the phase locked loop circuit may decrease as the magnitude of the power for controlling the phase locked loop circuit is fixed.

### SUMMARY

The present disclosure relates to an apparatus for generating a clock, capable of controlling power applied to a phase locked loop circuit based on signal quality of a signal received in response to a clock signal.

In some implementations, an apparatus for generating a clock may include a phase locked loop circuit to generate a first clock signal having a specified frequency through an oscillator, a monitoring circuit to monitor a first bit error rate (BER) of a first signal received in response to the first clock signal, and a control logic circuit to control the phase locked loop circuit based on a monitoring result. The control logic circuit may connect a first boosting current source, which is included in the phase locked loop circuit, to the oscillator, when the first bit error rate is equal to or greater than a preset threshold value, and disconnect a second boosting current source, which is previously connected to the oscillator, from the oscillator, when the first bit error rate is less than the threshold value.

In some implementations, a method for generating a clock may include monitoring a first bit error rate of a first signal received in response to a first clock signal having a specified frequency, connecting a first boosting current source included in a phase locked loop circuit to an oscillator, when the first bit error rate is equal to or greater than a preset threshold value, and disconnecting a second boosting current source, which is previously connected to the oscillator, from the oscillator, when the first bit error rate is less than the threshold value.

In some implementations, an apparatus for generating a clock may include a phase locked loop circuit to generate a first clock signal having a specified frequency through an inductor-capacitor oscillator, a monitoring circuit to monitor a first bit error rate of a first signal received in response to the first clock signal, and a control logic circuit to control the phase locked loop circuit based on a monitoring result. The inductor-capacitor oscillator may include an inductor-capacitor tank in which an inductor and a capacitor are connected in parallel, and a plurality of cells, in which each cell includes a plurality of transistors, the plurality of cells may be connected to each other in parallel, and the control logic circuit may connect a first cell from among the plurality of cells to the inductor-capacitor tank, when the first bit error rate is equal to or greater than a preset threshold value.

### BRIEF DESCRIPTION OF THE DRAWINGS

The above and other objects and features of the present disclosure will become apparent by describing in detail implementations thereof with reference to the accompanying drawings.

FIG. 1A is a block diagram illustrating an example of an apparatus for generating a clock.

FIG. 1B illustrates an example of a configuration in which a control logic circuit of FIG. 1A controls a phase locked loop circuit.

FIG. 2 illustrates an example of a configuration in which a control logic circuit controls a phase locked loop circuit using a boosting current source.

FIG. 3 illustrates an example of a configuration in which a control logic circuit controls a phase locked loop circuit using an over-clock current source.

FIG. 4A illustrates an example of a configuration in which a control logic circuit controls a gain of a loop filter.

FIG. 4B is a circuit diagram illustrating an example of a configuration of a phase detector and a loop filter connected to the oscillator of FIG. 4A.

FIG. 4C illustrates a gain of an example of a loop filter under control of a control logic circuit of FIG. 4A.

FIG. 5 illustrates an example of a configuration in which a control logic circuit controls a phase locked loop circuit using a boosting current source and an over-clock current source.

FIG. 6 illustrates an example of a configuration in which a control logic circuit controls a phase locked loop circuit using a boosting current source and a loop filter.

FIG. 7 illustrates an example of a configuration in which a control logic circuit controls a phase locked loop circuit using an over-clock current source and a loop filter.

FIG. 8 illustrates an example of a configuration in which a control logic circuit controls a phase locked loop circuit using a boosting current source, an over-clock current source, and a loop filter.

FIG. 9 is a flowchart illustrating an example of a method for controlling a phase locked loop circuit.

FIG. 10A is a flowchart illustrating an example of a method for controlling a phase locked loop circuit using a boosting current source.

FIG. 10B is a flowchart illustrating an example of a method for controlling a phase locked loop circuit in sequence of the flowchart illustrated in FIG. 10A depending on whether a control logic circuit is operated by background control.

FIG. 11A is a flowchart illustrating an example of a method for controlling a phase locked loop circuit using an over-clock current source.

FIG. 11B is a flowchart illustrating an example of a method for controlling a phase locked loop circuit using a boosting current source according to a bit error rate of a second signal.

FIG. 12 is a flowchart illustrating an example of a method for controlling a phase locked loop circuit by controlling a gain of a loop filter.

FIG. 13 illustrates an example of a clock generating device including an LC oscillator.

FIG. 14 is a flowchart illustrating an example of a method for controlling the clock generating device of FIG. 13.

FIG. 15 is a block diagram illustrating an example of a clock generating device further including a decoder.

### DETAILED DESCRIPTION

Hereinafter, implementations of the present disclosure will be described clearly and in detail, such which those skilled in the art may easily implement the present disclosure.

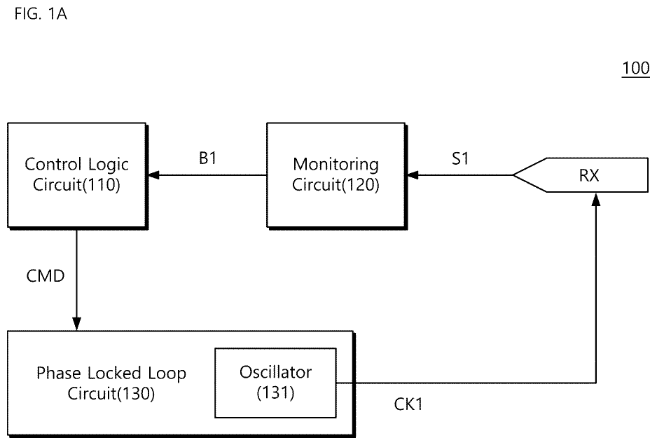

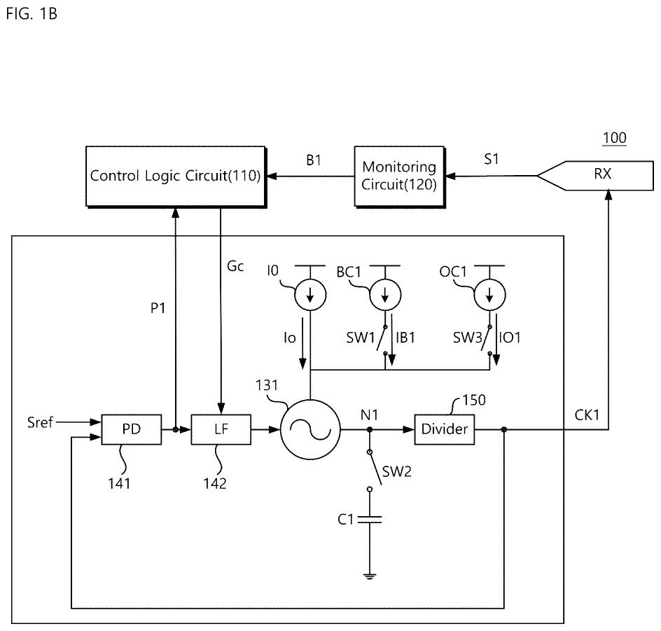

FIG. 1A is a block diagram illustrating an example of an apparatus (hereinafter, a clock generating device) for generating a clock. FIG. 1B illustrates an example of a configuration in which a control logic circuit of FIG. 1A controls a phase locked loop circuit.

Referring to FIGS. 1A and 1B, a clock generating device 100 may include a control logic circuit 110, a monitoring circuit 120, and a phase locked loop (PLL) circuit 130.

In some implementations, the clock generating device 100 may include the phase locked loop circuit 130 which generates a first clock signal CK1 having a specified frequency through an oscillator 131.

More specifically, the phase locked loop circuit 130 may generate the first clock signal CK1 having a specified frequency through the oscillator 131, based on a control signal CMD received from the control logic circuit 110.

For example, the phase locked loop circuit 130 may receive a reference signal Sref and output the first clock signal CK1 having the same frequency as the frequency of the reference signal Sref through the oscillator 131.

In this case, for example, the oscillator 131 may be understood as a digitally controlled oscillator (DCO) controlled by a digital code. However, for another example, the oscillator 131 may be understood as a voltage controlled oscillator (VCO) controlled by an input analog voltage.

In addition, for example, the oscillator 131 may be referred to as a ring oscillator including multiple inverters connected in series, but the present disclosure is not limited thereto.

In some implementations, the clock generating device 100 may include the monitoring circuit 120 which monitors a bit error rate (BER) of a first signal S1 received in response to the first clock signal CK1.

More specifically, the monitoring circuit 120 may monitor a first bit error rate B1 of a first signal S1 received through a receiver RX in response to the first clock signal CK1.

For example, the monitoring circuit 120 may monitor the first bit error rate B1 of the first signal S1 based on the distribution of the first signal S1 received through the receiver RX in response to the first clock signal CK1.

For another example, a signal to noise ratio (SNR) of the first signal S1 may be monitored, based on the distribution of the first signal S1 received through the receiver RX in response to the first clock signal CK1.

In other words, the monitoring circuit 120 may monitor (or measure) the signal quality (e.g., a bit error rate; SNR) of the first signal S1 received in response to the first clock signal CK1.

In some implementations, the clock generating device 100 may include the control logic circuit 110 which controls the phase locked loop circuit 130 depending on the monitoring result of the monitoring circuit 120.

The control logic circuit 110 may generate the control signal CMD for controlling the phase locked loop circuit 130 based on the monitoring result of the monitoring circuit 120.

The control logic circuit 110 may execute, for example, software (or program) to control at least one different component (e.g., the phase locked loop circuit 130) of the clock generating device 100, and may perform various data processing or operations. The control logic circuit 110 may include a central processing device, or a microprocessor, and may control the overall operation of the clock generating device 100. Therefore, it may be understood which the following operation performed by the clock generating device 100 is performed under the control of the control logic circuit 110.

In some implementations, the control logic circuit 110 may include an algorithm for controlling at least some of the components of the phase locked loop circuit 130. For example, the algorithm may be a software code programmed in the control logic circuit 110. For another example, the algorithm may be a hard code hardcoded in the control logic circuit 110, but the present disclosure is not limited thereto.

In some implementations, the control logic circuit 110 may control a current input to the oscillator 131 from the phase locked loop circuit 130 depending on the algorithm. In addition, the control logic circuit 110 may control a gain of a loop filter (LF) 142 included in the phase locked loop circuit 130 depending on the algorithm.

Referring to FIG. 1B, the control logic circuit 110 may control the magnitude of the current input to the oscillator 131 of the phase locked loop circuit 130 based on the first bit error rate B1 of the first signal S1.

More specifically, the control logic circuit 110 may connect at least some of current sources BC1 and OC1 included in the phase locked loop circuit 130 to the oscillator 131 based on the first bit error rate B1 of the first signal S1.

The control logic circuit 110 may connect the first boosting current source BC1 to the oscillator 131 in response to the first bit error rate B1 of the first signal S1 being greater than or equal to the preset threshold value. In this case, for example, the threshold value may be stored in an internal storage space of the clock generating device 100.

More specifically, the control logic circuit 110 may connect the first boosting current source BC1 to the oscillator 131 such that a first boosting current IB1 is applied to the oscillator 131 together with a base current Io in response to that the first bit error rate B1 of the first signal S1 is greater than or equal to the preset threshold value.

For example, the control logic circuit 110 may turn on a first switch SW1 interposed between the first boosting current source BC1 and the oscillator 131 in response to the first bit error rate B1 of the first signal S1 being greater than or equal to the preset threshold value.

Furthermore, the control logic circuit 110 may connect a first capacitor C1 corresponding to the first boosting current source BC1 to an output node N1 of the oscillator 131, together with the first boosting current source BC1.

More specifically, the control logic circuit 110 may connect the first capacitor C1 having capacitance corresponding to the first boosting current IB1 to the output node N1 of the oscillator 131 in response to the first boosting current source BC1 being connected to the oscillator 131.

For example, the control logic circuit 110 may turn on a second switch SW2 interposed between the first capacitor C1 and the oscillator 131 in response to the first boosting current source BC1 being connected to the oscillator 131.

However, in this case, referring to FIG. 1B, the first capacitor C1 is illustrated as a single capacitor, but the present disclosure is not limited thereto, and the first capacitor C1 may also be referred to as a component in which multiple capacitors are connected in series and/or in parallel.

In some implementations, the control logic circuit 110 may connect a first over-clock current source OC1 to the oscillator 131 in response to the first bit error rate B1 of the first signal S1 being greater than or equal to the preset threshold value.

More specifically, the control logic circuit 110 may connect the first over-clock current source OC1 to the oscillator 131 such that a first over-clock current IO1 is applied to the oscillator 131 together with the base current Io in response to the first bit error rate B1 of the first signal S1 being greater than or equal to the preset threshold value.

For example, the control logic circuit 110 may turn on a third switch SW3 interposed between the first over-clock current source OC1 and the oscillator 131 in response to the first bit error rate B1 of the first signal S1 being greater than or equal to the preset threshold value.

Furthermore, the control logic circuit 110 may control a coefficient of a divider 150 in response to the first over-clock current source OC1 being connected to the oscillator 131.

More specifically, the control logic circuit 110 may control the coefficient of the divider 150 with a value obtained by dividing the current, which is input to the oscillator 131, by the base current Io, in response to the first over-clock current source OC1 being connected to the oscillator 131.

In this case, the first over-clock current IO1 may have a current value which is an integer multiple of the base current Io.

Therefore, for example, the control logic circuit 110 may control the coefficient of the divider 150 to be ‘4’, in response to the first over-clock current IO1 having a current value (3*Io), which is three times the base current Io, being applied to the oscillator 131.

Referring to the above-described configurations, the control logic circuit 110 may increase the current applied to the oscillator 131 in response to the first bit error rate B1 of the first signal S1 being greater than or equal to the preset threshold value.

Accordingly, the control logic circuit 110 may reduce the first bit error rate B1 of the first signal S1 received in response to the first clock signal CK1 output through the oscillator 131.

In addition, the control logic circuit 110 may control the frequency of the signal output from the oscillator 131 in response to an increase in the current applied to the oscillator 131.

Accordingly, the control logic circuit 110 may reduce the first bit error rate B1 of the first signal S1 received in response to the first clock signal CK1 and maintain the frequency of the first clock signal CK1.

In addition, the control logic circuit 110 may disconnect at least some of the current sources BC1 and OC1 connected to the oscillator 131 from the oscillator 131, in the phase locked loop circuit 130.

More specifically, the control logic circuit 110 may disconnect at least some of the current sources BC1 and OC1, which are previously connected to the oscillator 131, from the oscillator 131 in response to the first bit error rate B1 of the first signal S1 being less than the preset threshold value.

The control logic circuit 110 may disconnect the first boosting current source BC1, which is previously connected to the oscillator 131, from the oscillator 131 in response to the first bit error rate B1 of the first signal S1 being less than the preset threshold value. In this case, it is assumed which the first boosting current source BC1 is previously connected to the oscillator 131.

More specifically, in response to the first bit error rate B1 of the first signal S1 being less than the preset threshold value, the control logic circuit 110 may disconnect the first boosting current source BC1 from the oscillator 131 such that the current applied to the oscillator 131 is decreased.

For example, in response to the first bit error rate B1 of the first signal S1 being less than the preset threshold value, the control logic circuit 110 may turn off the first switch SW1 interposed between the first boosting current source BC1, which is previously connected to the oscillator 131, and the oscillator 131.

Furthermore, the control logic circuit 110 may disconnect the first capacitor C1 corresponding to the first boosting current source BC1 from the output node N1 of the oscillator 131, together with the first boosting current source BC1.

For example, the control logic circuit 110 may turn off the second switch SW2 interposed between the first capacitor C1 and the oscillator 131 in response to the disconnection of the first boosting current source BC1 and the oscillator 131.

Furthermore, the control logic circuit 110 may disconnect the first over-clock current source OC1 from the oscillator 131, in response to the first bit error rate B1 of the first signal S1 being less than the preset threshold value. In this case, it is assumed which the first over-clock current source OC1 is previously connected to the oscillator 131.

More specifically, in response to the first bit error rate B1 of the first signal S1 being less than the preset threshold value, the control logic circuit 110 may disconnect the first over-clock current source OC1 from the oscillator 131 such that the current applied to the oscillator 131 is decreased.

For example, the control logic circuit 110 may turn off the third switch SW3 interposed between the first over-clock current source OC1, which is previously connected to the oscillator 131, and the oscillator 131, in response to the first bit error rate B1 of the first signal S1 being less than the preset threshold value.

Furthermore, the control logic circuit 110 may control the coefficient of the divider 150 in response to a disconnection between the first over-clock current source OC1 and the oscillator 131.

More specifically, the control logic circuit 110 may control the coefficient of the divider 150 with a value obtained by dividing the current, which is input to the oscillator 131 by the base current Io, in response to the disconnection of the first over-clock current source OC1 and the oscillator 131.

For example, the control logic circuit 110 may control the coefficient of the divider 150 to be ‘1’, in response to the disconnection between the first over-clock current source OC1 and the oscillator 131.

Referring to the above-described configurations, the control logic circuit 110 may reduce the current applied to the oscillator 131 in response to the first bit error rate B1 of the first signal S1 being less than the preset threshold value.

Accordingly, the control logic circuit 110 may minimize the power consumed by the phase locked loop circuit 130 to generate the first clock signal CK1.

In addition, the control logic circuit 110 may control the frequency of the signal output from the oscillator 131, in response to a decrease in the current applied to the oscillator 131.

Accordingly, the control logic circuit 110 may reduce the power consumption of the phase locked loop circuit 130 and maintain the frequency of the first clock signal CK1.

Accordingly, the control logic circuit 110 of the present disclosure may increase or decrease the magnitude of the current (or power) applied to the phase locked loop circuit 130, based on the signal quality (e.g., the first bit error rate B1) of the first signal S1 received in response to the first clock signal CK1.

Accordingly, the clock generating device 100 of the present disclosure may improve power efficiency for the phase locked loop circuit 130, based on the signal quality of the first signal S1 received in response to the first clock signal CK1.

In addition, the control logic circuit 110 may control the gain of the loop filter 142 based on a phase difference P1 between the first clock signal CK1, which is generated from the oscillator 131, and the reference signal Sref.

More specifically, the control logic circuit 110 may detect the phase difference P1 between the first clock signal CK1 and the reference signal Sref by using the phase detector PD 141. In this case, the control logic circuit 110 may detect the phase difference P1 between a signal, which is obtained by dividing the first clock signal CK1 by an arbitrary number (e.g., “N”), and the reference signal Sref.

Furthermore, the control logic circuit 110 may control a gain of the loop filter 142, based on the phase difference P1.

More specifically, the control logic circuit 110 may generate a gain control signal Gc for controlling the gain of the loop filter 142 based on the phase difference P1 between the first clock signal CK1 and the reference signal Sref.

In some implementations, the control logic circuit 110 may control the gain of the loop filter 142, such that the first bit error rate B1 of the first signal S1 in response to the first clock signal CK1 is decreased, based on the phase difference P1 between the first clock signal CK1 and the reference signal Sref.

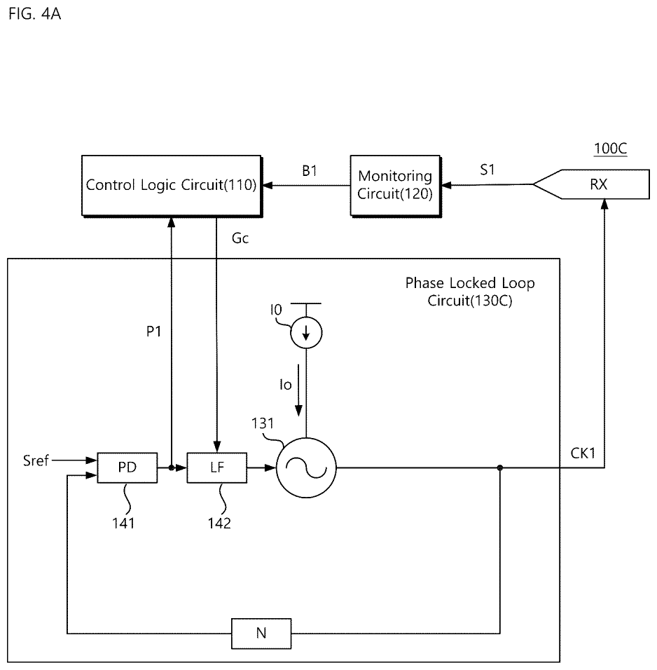

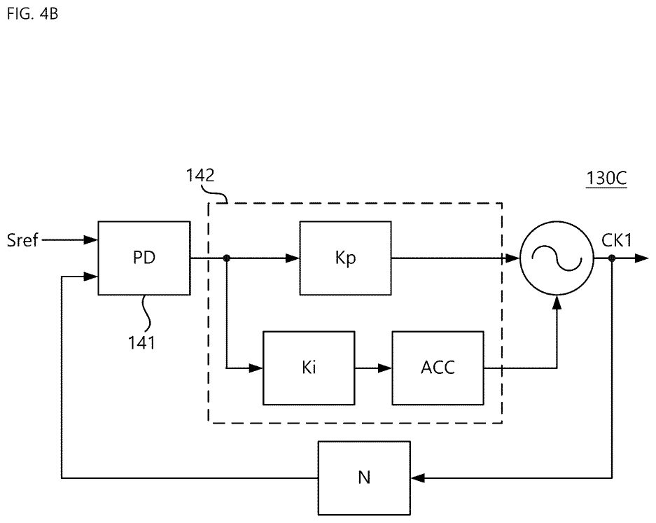

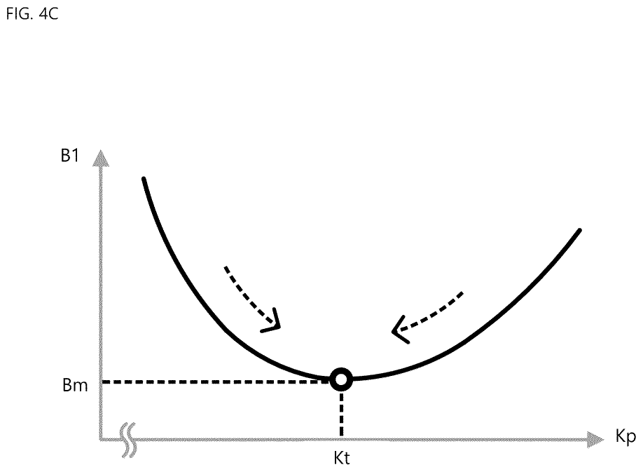

In this case, for example, the control logic circuit 110 may control the gain of the loop filter 142 using an autocorrelation technique. However, the detailed description thereof will be made later with reference to FIGS. 4A to 4C.

Referring to the above-described configuration, the control logic circuit 110 may control the gain of the loop filter 142 to control the signal quality (e.g., the first bit error rate B1) of the first signal S1 received in response to the first clock signal CK1.

Accordingly, the clock generating device 100 of the present disclosure may improve the signal quality of the first signal S1 received in response to the first clock signal CK1 without increasing the power consumption applied to the phase locked loop circuit 130.

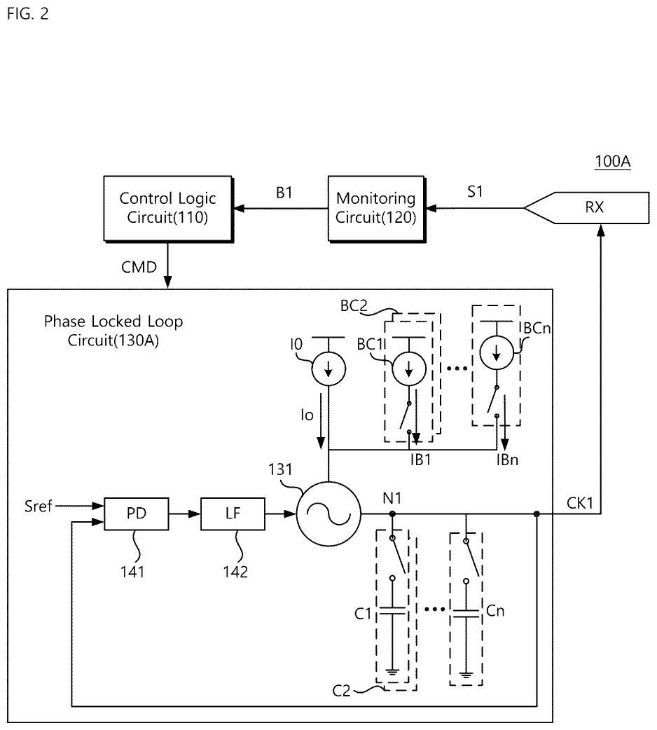

FIG. 2 illustrates an example of a configuration in which a control logic circuit controls a phase locked loop circuit using a boosting current source.

Referring to FIG. 2, a clock generating device 100A may include the control logic circuit 110, the monitoring circuit 120, and a phase locked loop circuit 130A.

In this case, the clock generating device 100A and the phase locked loop circuit 130A illustrated in FIG. 2 may be understood as examples of the clock generating device 100 and the phase locked loop circuit 130 illustrated in FIG. 1A.

Accordingly, the same reference numeral will be assigned to the same component or substantially the same component as the above-described component, and the duplication thereof will be omitted to avoid redundancy.

In some implementations, the phase locked loop circuit 130A may include a plurality of boosting current sources BC1 to BCn connected to the oscillator 131.

In addition, the phase locked loop circuit 130A may include a plurality of capacitors C1 to Cn connected to the output node N1 of the oscillator 131.

In this case, it may be understood which each of the plurality of capacitors C1 to Cn corresponds to the plurality of boosting current sources BC1 to BCn. For example, the plurality of capacitors C1 to Cn may have capacitances corresponding to currents of the plurality of boosting current sources BC1 to BCn, respectively.

In some implementations, the control logic circuit 110 may connect at least some of the plurality of boosting current sources BC1 to BCn to the oscillator 131 in response to the first bit error rate B1 of the first signal S1 being greater than or equal to the preset threshold value.

For example, the control logic circuit 110 may connect the first boosting current source BC1 among the plurality of boosting current sources BC1 to BCn to the oscillator 131, in response to the first bit error rate B1 of the first signal S1 being greater than or equal to the preset threshold value.

The control logic circuit 110 may connect the first boosting current source BC1 to the oscillator 131, such that the first boosting current IB1 is additionally applied to the oscillator 131 together with the base current Io, in response to that the first bit error rate B1 of the first signal S1 is greater than or equal to the preset threshold value.

To this end, the control logic circuit 110 may turn on a switch interposed between the first boosting current source BC1 and the oscillator 131.

Furthermore, the control logic circuit 110 may connect the first capacitor C1, which corresponds to the first boosting current source BC1, to the output node N1 of the oscillator 131, together with the first boosting current source BC1.

The control logic circuit 110 may connect the first capacitor C1 having a capacitance corresponding to the first boosting current IB1 to the output node N1 of the oscillator 131 in response to the first boosting current source BC1 being connected to the oscillator 131.

To this end, the control logic circuit 110 may turn on the switch interposed between the first capacitor C1 and the oscillator 131.

For another example, the control logic circuit 110 may connect the first capacitor C1 and the second capacitor C2 to the output node N1 of the oscillator 131, in response to the first boosting current source BC1 being connected to the oscillator 131.

However, as at least some of the plurality of boosting current sources BC1 to BCn are connected to the oscillator 131, the number and configuration of capacitors connected by the control logic circuit 110 to the output node N1 are not limited to the above examples.

Referring to the above-described configurations, the control logic circuit 110 may increase the current applied to the oscillator 131, in response to the first bit error rate B1 of the first signal S1 being greater than or equal to the preset threshold value.

Accordingly, the control logic circuit 110 may reduce the first bit error rate B1 of the first signal S1 received in response to the first clock signal CK1 output through the oscillator 131.

In addition, the control logic circuit 110 may connect a capacitor to the output node N1 of the oscillator 131 in response to an increase in the current applied to the oscillator 131.

Accordingly, the control logic circuit 110 may reduce the first bit error rate B1 of the first signal S1 received in response to the first clock signal CK1 while maintaining the frequency of the first clock signal CK1.

In some implementations, the control logic circuit 110 may disconnect at least some of the plurality of boosting current sources BC1 to BCn connected to the oscillator 131 in the phase locked loop circuit 130A, from the oscillator 131.

More specifically, in response to the first bit error rate B1 of the first signal S1 being less than the preset threshold value, the control logic circuit 110 may disconnect at least some of the current sources previously connected to the oscillator 131, from the oscillator 131.

For example, in response to the first bit error rate B1 of the first signal S1 being less than the preset threshold value, the control logic circuit 110 may disconnect the second boosting current source BC2, which is previously connected to the oscillator 131, among the plurality of boosting current sources BC1 to BCn, from the oscillator 131. In this case, it is assumed which the second boosting current source BC2 is previously connected to the oscillator 131.

In response to the first bit error rate B1 of the first signal S1 being less than the preset threshold value, the control logic circuit 110 may disconnect the second boosting current source BC2 from the oscillator 131 such that the current applied to the oscillator 131 is decreased.

To this end, the control logic circuit 110 may turn off a switch interposed between the oscillator 131 and the second boosting current source BC2 previously connected to the oscillator 131.

Furthermore, in response to the disconnection of the second boosting current source BC2 from the oscillator 131, the control logic circuit 110 may disconnect the second capacitor C2 corresponding to the second boosting current source BC2 from the oscillator 131. To this end, the control logic circuit 110 may turn off a switch interposed between the second capacitor C2 and the output node N1 of the oscillator 131.

Referring to the above-described configurations, the control logic circuit 110 may reduce the current applied to the oscillator 131 in response to the first bit error rate B1 of the first signal S1 being less than the preset threshold value.

Accordingly, the control logic circuit 110 may minimize the power consumed by the phase locked loop circuit 130A to generate the first clock signal CK1.

Accordingly, the control logic circuit 110 of the present disclosure may increase or decrease the magnitude of the current (or power) applied to the phase locked loop circuit 130A, based on the signal quality of the first signal S1 received in response to the first clock signal CK1.

Accordingly, the clock generating device 100A of the present disclosure may improve power efficiency for the phase locked loop circuit 130A, based on the signal quality of the first signal S1 received in response to the first clock signal CK1.

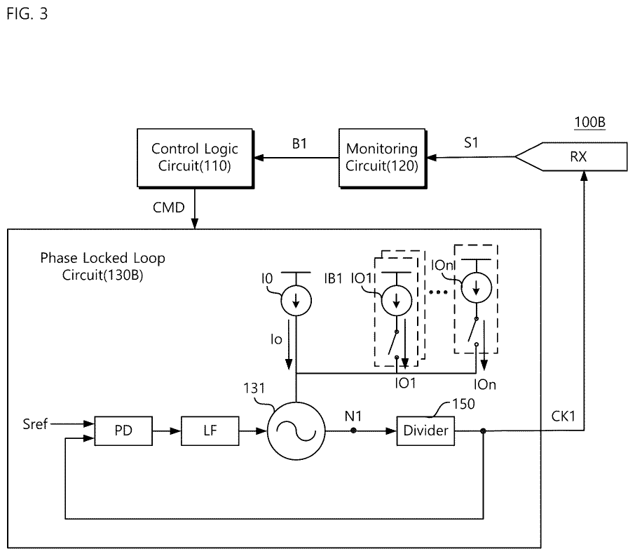

FIG. 3 illustrates an example of a configuration in which a control logic circuit controls a phase locked loop circuit using an over-clock current source.

Referring to FIG. 3, a clock generating device 100B may include the control logic circuit 110, the monitoring circuit 120, and a phase locked loop circuit 130B.

In this case, the clock generating device 100B and the phase locked loop circuit 130B illustrated in FIG. 3 may be understood as examples of the clock generating device 100 and the phase locked loop circuit 130 illustrated in FIG. 1A.

Accordingly, the same reference numeral will be assigned to the same component or substantially the same component as the above-described component, and the duplication thereof will be omitted to avoid redundancy.

In some implementations, the phase locked loop circuit 130B may include a plurality of over-clock current sources OC1 to OCn connected to the oscillator 131.

In addition, the phase locked loop circuit 130B may include the divider 150 connected to the output node N1 of the oscillator 131.

In some implementations, the control logic circuit 110 may connect at least some of the plurality of over-clock current sources OC1 to OCn to the oscillator 131 in response to the first bit error rate B1 of the first signal S1 being greater than or equal to the preset threshold value.

For example, the control logic circuit 110 may connect the first over-clock current source OC1 among the plurality of over-clock current sources OC1 to OCn, to the oscillator 131, in response to the first bit error rate B1 of the first signal S1 being greater than or equal to the preset threshold value.

The control logic circuit 110 may connect the first over-clock current source OC1 to the oscillator 131 such that the first over-clock current IO1 is applied to the oscillator 131 together with the base current Io, in response to the first bit error rate B1 of the first signal S1 being greater than or equal to the preset threshold value.

To this end, the control logic circuit 110 may turn on a switch interposed between the first over-clock current source OC1 and the oscillator 131.

Furthermore, the control logic circuit 110 may control the coefficient of the divider 150, in response to the first over-clock current source OC1 being connected to the oscillator 131.

The control logic circuit 110 may control the coefficient of the divider 150 as a value which is obtained by dividing the current input to the oscillator 131 by the base current Io.

In this case, the first over-clock current IO1 may have a current value which is an integer multiple of the base current Io. For example, the first over-clock current IO1 may have a current value which is three times the base current Io.

Accordingly, for example, the control logic circuit 110 may control the coefficient of the divider 150 to be ‘3’ in response to the first over-clock current source OC1 being connected to the oscillator 131.

Referring to the above-described configurations, the control logic circuit 110 may increase the current applied to the oscillator 131, in response to the first bit error rate B1 of the first signal S1 being greater than or equal to the preset threshold value.

Accordingly, the control logic circuit 110 may reduce the first bit error rate B1 of the first signal S1 received in response to the first clock signal CK1 output through the oscillator 131.

In addition, the control logic circuit 110 may control the frequency of the signal output from the oscillator 131 in response to an increase in the current applied to the oscillator 131.

Accordingly, the control logic circuit 110 may reduce the first bit error rate B1 of the first signal S1 received in response to the first clock signal CK1 while maintaining the frequency of the first clock signal CK1.

In some implementations, the control logic circuit 110 may disconnect at least some of the plurality of over-clock current sources OC1 to OCn from the oscillator 131 in response to the first bit error rate B1 of the first signal S1 being less than the preset threshold value

For example, in response to the first bit error rate B1 of the first signal S1 being less than the preset threshold value, the control logic circuit 110 may disconnect the second over-clock current source OC2, which is previously connected to the oscillator 131, among the plurality of over-clock current sources OC1 to OCn from the oscillator 131. In this case, it is assumed which the second over-clock current source OC2 is previously connected to the oscillator 131.

In response to the first bit error rate B1 being less than the preset threshold value, the control logic circuit 110 may disconnect the second over-clock current source OC2, which is previously connected to the oscillator 131, among the plurality of over-clock current sources OC1 to OCn, from the oscillator 131 such that the current applied to the oscillator 131 decreases.

To this end, the control logic circuit 110 may turn off a switch interposed between the second over-clock current source OC2 and the oscillator 131.

Furthermore, the control logic circuit 110 may control the coefficient of the divider 150 in response to the disconnection of the second over-clock current source OC2 from the oscillator 131.

For example, the control logic circuit 110 may control the coefficient of the divider 150 to be “1” in response to a disconnection between the second over-clock current source OC2 and the oscillator 131.

Referring to the above-described configurations, the control logic circuit 110 may reduce the current applied to the oscillator 131 in response to the first bit error rate B1 of the first signal S1 being less than the preset threshold value.

Accordingly, the control logic circuit 110 may minimize the power consumed by the phase locked loop circuit 130B to generate the first clock signal CK1.

Accordingly, the control logic circuit 110 may increase or decrease the magnitude of the current (or power) applied to the phase locked loop circuit 130B, based on the signal quality of the first signal S1 received in response to the first clock signal CK1.

Accordingly, the clock generating device 100B of the present disclosure may improve power efficiency for the phase locked loop circuit 130B, based on the signal quality of the first signal S1 received in response to the first clock signal CK1.

FIG. 4A illustrates an example of a configuration in which a control logic circuit controls a gain of a loop filter. FIG. 4B is a circuit diagram illustrating an example of a configuration of a phase detector and a loop filter connected to the oscillator of FIG. 4A. FIG. 4C illustrates a gain of an example of a loop filter under control of the control logic circuit of FIG. 4A.

Referring to FIGS. 4A to 4C together, a clock generating device 100C may include the control logic circuit 110, the monitoring circuit 120, and a phase locked loop circuit 130C.

In addition, the phase locked loop circuit 130C may include a phase detector 141 and the loop filter 142.

In this case, the clock generating device 100C and the phase locked loop circuit 130C illustrated in FIG. 4A may be understood as examples of the clock generating device 100 and the phase locked loop circuit 130 illustrated in FIG. 1A.

Accordingly, the same reference numeral will be assigned to the same component or substantially the same component as the above-described component, and the duplication thereof will be omitted to avoid redundancy.

Referring to FIGS. 4A and 4B together, the phase locked loop circuit 130C may include the phase detector 141 which compares the phase of the first clock signal CK1 with the phase of the reference signal Sref to output the phase difference P1.

More specifically, the phase detector 141 may compare the phase of the first clock signal CK1 divided by an arbitrary number ‘N’ with the phase of the reference signal Sref to output the phase difference P1.

In this case, the phase detector 141 may be referred to as a bang phase detector BBPD which outputs phase error information from each of the first clock signal CK1 and the reference signal Sref, but the present disclosure is not limited thereto.

In addition, the phase locked loop circuit 130C may include the loop filter 142 connected between the phase detector 141 and the oscillator 131.

In some implementations, the loop filter 142 may apply a proportional gain Kp to the phase difference P1 output from the phase detector 141. In addition, the loop filter 142 may apply an integral path gain Ki to the phase difference P1 through an accumulator ACC.

Accordingly, the loop filter 142 may control the oscillator 131 such that the oscillator 131 outputs a clock signal having a frequency of the reference signal Sref.

In some implementations, the control logic circuit 110 may generate the gain control signal Gc for controlling the loop filter 142 based on the phase difference P1.

More specifically, the control logic circuit 110 may provide the gain control signal Gc for controlling the proportional gain Kp of the loop filter 142, to the loop filter 142 based on the phase difference P1.

Accordingly, the control logic circuit 110 may control the proportional gain Kp of the loop filter 142, based on the phase difference P1 between the first clock signal CK1 and the reference signal Sref generated from the oscillator 131.

Furthermore, the control logic circuit 110 may control the phase (or frequency) of the first clock signal CK1 and the first bit error rate B1 of the first signal S1 by controlling the proportional gain Kp of the loop filter 142.

In this case, it may be understood which the first bit error rate B1 of the first signal S1 has a different value depending on the phase (or the proportional gain Kp of the loop filter 142) of the first clock signal CK1.

Referring to FIG. 4C, the control logic circuit 110 may control the gain of the loop filter 142 such that the first signal S1 has the maximum signal quality (e.g., SNR).

More specifically, the control logic circuit 110 may control the gain of the loop filter 142 to a first proportional gain Kt, which corresponds to the minimum value Bm of the first bit error rate B1, such that the first bit error rate B1 has the minimum value Bm.

In this case, for example, the control logic circuit 110 may control the proportional gain Kp of the loop filter 142 to the first proportional gain Kt such that the first bit error rate B1 of the first clock signal CK1 has the minimum value Bm using an autocorrelation scheme.

However, the method for controlling the proportional gain Kp of the loop filter 142 by the control logic circuit 110 is not limited to the above-described example.

Referring to the above-described configuration, the control logic circuit 110 may control the proportional gain Kp of the loop filter 142 to control the signal quality (e.g., the first bit error rate B1) of the first signal S1 received in response to the first clock signal CK1.

Accordingly, the clock generating device 100C of the present disclosure may improve the signal quality of the first signal S1 in response to the first clock signal CK1 while maintaining the power applied to the phase locked loop circuit 130C.

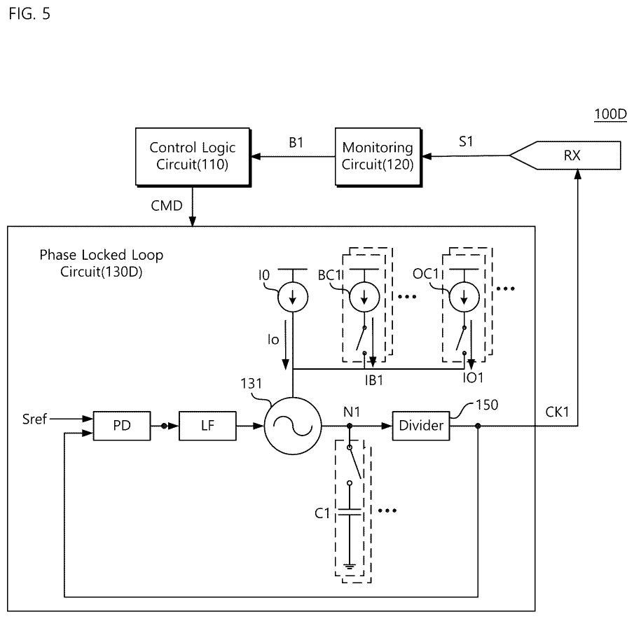

FIG. 5 illustrates an example of a configuration in which a control logic circuit controls a phase locked loop circuit using a boosting current source and an over-clock current source.

Referring to FIG. 5, a clock generating device 100D may include the control logic circuit 110, the monitoring circuit 120, and a phase locked loop circuit 130D.

In this case, the clock generating device 100D and the phase locked loop circuit 130D illustrated in FIG. 5 may be understood as examples of the clock generating device 100 and the phase locked loop circuit 130 illustrated in FIG. 1A.

Accordingly, the same reference numeral will be assigned to the same component or substantially the same component as the above-described component, and the duplication thereof will be omitted to avoid redundancy.

In some implementations, the phase locked loop circuit 130D may include the plurality of boosting current sources BC1 to BCn connected to the oscillator 131. In addition, the phase locked loop circuit 130D may include the plurality of capacitors C1 to Cn connected to the output node N1 of the oscillator 131.

In this case, it may be understood which the plurality of capacitors C1 to Cn correspond to the plurality of boosting current sources BC1 to BCn, respectively. For example, the plurality of capacitors C1 to Cn may have capacitance corresponding to currents of the plurality of boosting current sources BC1 to BCn, respectively.

Furthermore, the phase locked loop circuit 130D may include the plurality of over-clock current sources OC1 to OCn connected to the oscillator 131. Furthermore, the phase locked loop circuit 130D may include the divider 150 connected to the output node N1 of the oscillator 131.

In some implementations, the control logic circuit 110 may connect at least some of the plurality of boosting current sources BC1 to BCn to the oscillator 131 in response to the first bit error rate B1 of the first signal S1 being greater than or equal to the preset threshold value.

For example, the control logic circuit 110 may connect the first boosting current source BC1 among the plurality of boosting current sources BC1 to BCn to the oscillator 131 in response to the first bit error rate B1 of the first signal S1 being greater than or equal to the preset threshold value.

The control logic circuit 110 may connect the first boosting current source BC1 to the oscillator 131 such that the first boosting current IB1 is additionally applied to the oscillator 131 together with the base current Io in response to the first bit error rate B1 of the first signal S1 being greater than or equal to the preset threshold value.

In addition, the control logic circuit 110 may connect the first capacitor C1, which corresponds to the first boosting current source BC1, to the output node N1 of the oscillator 131 in response to the first boosting current source BC1 being connected to the oscillator 131.

Furthermore, the control logic circuit 110 may connect at least some of the over-clock current sources OC1 to OCn to the oscillator 131 when the first bit error rate B1 is greater than or equal to a preset threshold value in the state that at least some of the plurality of boosting current sources BC1 to BCn are connected to the oscillator 131.

For example, the control logic circuit 110 may connect at least some of the plurality of over-clock current sources OC1 to OCn to the oscillator 131 when the first bit error rate B1 is greater than or equal to a preset threshold value in the state that the first boosting current source BC1 is connected to the oscillator 131.

For another example, the control logic circuit 110 may connect the first over-clock current source OC1 among the plurality of over-clock current sources OC1 to OCn, to the oscillator 131, when the first bit error rate B1 is greater than or equal to the preset threshold value in the state that each of the plurality of boosting current sources BC1 to BCn is connected to the oscillator 131.

Furthermore, the control logic circuit 110 may control the coefficient of the divider 150 in response to the first over-clock current source OC1 being connected to the oscillator 131. In this case, the control logic circuit 110 may control the coefficient of the divider 150 to a value obtained by dividing the current input to the oscillator 131 by the base current Io.

For example, the control logic circuit 110 may control the coefficient of the divider 150 to be ‘3’, in response to the first over-clock current IO1, which is two times the base current Io, being applied to the oscillator 131 through the first over-clock current source OC1.

In this case, for example, each of the plurality of over-clock current sources OC1 to OCn may output a second current (e.g., the first over-clock current IO1) greater than the first current (e.g., the first boosting current IB1) output by each of the plurality of boosting current sources BC1 to BCn.

Through the above-described configurations, the clock generating device 100D may improve the signal quality of the first signal S1 by increasing the current (or power) applied to the phase locked loop circuit 130D based on the first bit error rate B1 of the first signal S1.

In some implementations, when the first bit error rate B1 of the first signal S1 is less than the preset threshold value, the control logic circuit 110 may disconnect at least some of the plurality of boosting current sources BC1 to BCn from the oscillator 131.

For example, in response to the first bit error rate B1 of the first signal S1 being less than the preset threshold value, the control logic circuit 110 may disconnect the second boosting current source BC2, which is previously connected to the oscillator 131, among the plurality of boosting current sources BC1 to BCn, from the oscillator 131.

Furthermore, in response to the disconnection of the second boosting current source BC2 from the oscillator 131, the control logic circuit 110 may disconnect the second capacitor C2 corresponding to the second boosting current source BC2 from the output node N1 of the oscillator 131.

Furthermore, the control logic circuit 110 may disconnect at least some of the over-clock current sources OC1 to OCn from the oscillator 131 when the first bit error rate B1 is less than the preset threshold value, in the state that at least some of the plurality of boosting current sources BC1 to BCn are disconnected from the oscillator 131.

For example, the control logic circuit 110 may disconnect at least some of the plurality of over-clock current sources OC1 to OCn from the oscillator 131, when the first bit error rate B1 is less than the preset threshold value in the state that the first boosting current source BC1 is disconnected from the oscillator 131.

For another example, the control logic circuit 110 may disconnect the second over-clock current source OC2 from the oscillator 131 when the first bit error rate B1 is greater than or equal to the preset threshold value in the state that each of the plurality of boosting current sources BC1 to BCn is disconnected from the oscillator 131. In this case, it is assumed which the second over-clock current source OC2 is previously connected to the oscillator 131.

Furthermore, the control logic circuit 110 may control the coefficient of the divider 150 in response to the disconnection of the second over-clock current source OC2 from the oscillator 131. In this case, the control logic circuit 110 may control the coefficient of the divider 150 to a value obtained by dividing the current input to the oscillator 131 by the base current Io.

For example, the control logic circuit 110 may control the coefficient of the divider 150 to be ‘1’ in response to the disconnection of the second over-clock current source OC2 from the oscillator 131.

Referring to the above-described configurations, the control logic circuit 110 may control the current applied to the oscillator 131 by using at least some of the plurality of boosting current sources BC1 to BCn, based on the first bit error rate B1 of the first signal S1.

Subsequently, the control logic circuit 110 may control the connection between the plurality of boosting current sources BC1 to BCn and the oscillator 131, and then control the current applied to the oscillator 131 by using at least some of the plurality of over-clock current sources OC1 to OCn based on the first bit error rate B1 of the first signal S1.

Accordingly, the clock generating device 100D of the present disclosure may increase the accuracy of an operation for controlling power for the phase locked loop circuit 130D based on the first bit error rate B1 of the first signal S1.

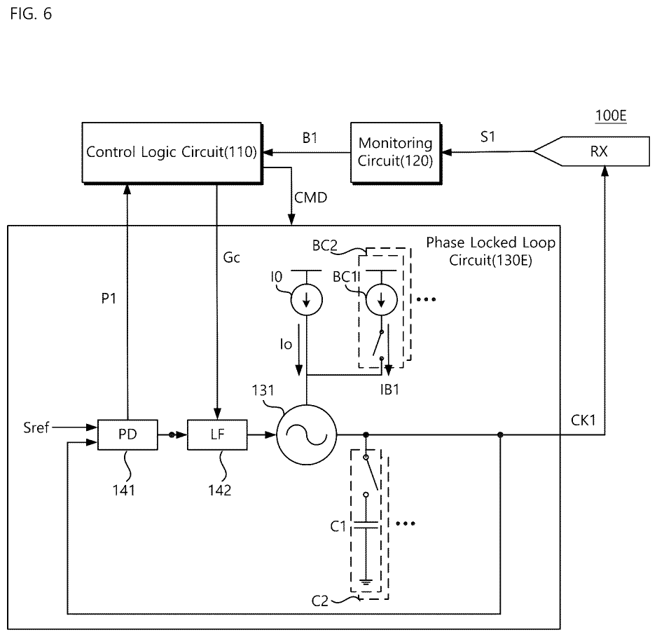

FIG. 6 illustrates an example of a configuration in which a control logic circuit controls a phase locked loop circuit using a boosting current source and a loop filter.

Referring to FIG. 6, a clock generating device 100E may include the control logic circuit 110, the monitoring circuit 120, and a phase locked loop circuit 130E.

In this case, the clock generating device 100E and the phase locked loop circuit 130E illustrated in FIG. 6 may be understood as examples of the clock generating device 100 and the phase locked loop circuit 130 illustrated in FIG. 1A. Accordingly, the same reference numeral will be assigned to the same component or substantially the same component as the above-described component, and the duplication thereof will be omitted to avoid redundancy.

In some implementations, the phase locked loop circuit 130E may include the plurality of boosting current sources BC1 to BCn connected to the oscillator 131. In addition, the phase locked loop circuit 130E may include the plurality of capacitors C1 to Cn connected to the output node N1 of the oscillator 131.

In some implementations, the control logic circuit 110 may connect at least some of the plurality of boosting current sources BC1 to BCn to the oscillator 131 in response to the first bit error rate B1 of the first signal S1 being greater than or equal to the preset threshold value.

For example, the control logic circuit 110 may connect the first boosting current source BC1 among the plurality of boosting current sources BC1 to BCn to the oscillator 131, in response to the first bit error rate B1 of the first signal S1 being greater than or equal to the preset threshold value.

The control logic circuit 110 may connect the first boosting current source BC1 to the oscillator 131 such that the first boosting current IB1 is additionally applied to the oscillator 131 together with the base current Io, in response to the first bit error rate B1 of the first signal S1 being greater than or equal to the preset threshold value.

In addition, the control logic circuit 110 may connect the first capacitor C1 corresponding to the first boosting current source BC1 to the output node N1 of the oscillator 131, in response to the first boosting current source BC1 being connected to the oscillator 131.

Meanwhile, when the first bit error rate B1 of the first signal S1 is less than the preset threshold value, the control logic circuit 110 may disconnect at least some of the plurality of boosting current sources BC1 to BCn from the oscillator 131.

For example, in response to the first bit error rate B1 of the first signal S1 being less than the preset threshold value, the control logic circuit 110 may disconnect the second boosting current source BC2, which is previously connected to the oscillator 131, among the plurality of boosting current sources BC1 to BCn, from the oscillator 131. In this case, it is assumed which the second boosting current source BC2 is previously connected to the oscillator 131.

Furthermore, in response to the disconnection of the second boosting current source BC2 from the oscillator 131, the control logic circuit 110 may disconnect the second capacitor C2 corresponding to the second boosting current source BC2 from the output node N1 of the oscillator 131.

Furthermore, the control logic circuit 110 may control the connection between at least some of the plurality of boosting current sources BC1 to BCn and the oscillator 131, and then control the gain of the loop filter 142 based on the phase difference P1 between the first clock signal CK1 generated from the oscillator 131 and the reference signal Sref.

For example, the control logic circuit 110 may detect the phase difference P1 between the first clock signal CK1 and the reference signal Sref by using the phase detector 141 in the state that at least some of the plurality of boosting current sources BC1 to BCn are connected to the oscillator 131.

Furthermore, the control logic circuit 110 may control a gain of the loop filter 142 based on the phase difference P1. More specifically, the control logic circuit 110 may generate the gain control signal Gc for controlling a gain (e.g., the proportional gain Kp of FIG. 4B) of the loop filter 142 based on the phase difference P1 between the first clock signal CK1 and the reference signal Sref.

In other words, the control logic circuit 110 may control the gain of the loop filter 142 based on the phase difference P1 between the first clock signal CK1 and the reference signal Sref, such that the first bit error rate B1 of the first signal S1 is decreased in response to the first clock signal CK1, in the state that at least some of the plurality of boosting current sources BC1 to BCn are connected to the oscillator 131.

Referring to the above-described configuration, the control logic circuit 110 may control the current applied to the oscillator 131 by using at least some of the plurality of boosting current sources BC1 to BCn, based on the first bit error rate B1 of the first signal S1.

Subsequently, the control logic circuit 110 may improve the signal quality of the first signal S1 by controlling the gain of the loop filter 142.

In other words, the clock generating device 100E of the present disclosure may improve the signal quality of the first signal S1, in the state while maintaining power consumption for the phase locked loop circuit 130E, after controlling the power applied to the phase locked loop circuit 130E using a boosting current source.

Accordingly, the clock generating device 100E of the present disclosure may minimize an operation of controlling the power applied to the phase locked loop circuit 130E to improve the signal quality of the first signal S1.

Accordingly, the clock generating device 100E may minimize the consumption of power applied to the phase locked loop circuit 130E to improve the signal quality of the first signal S1.

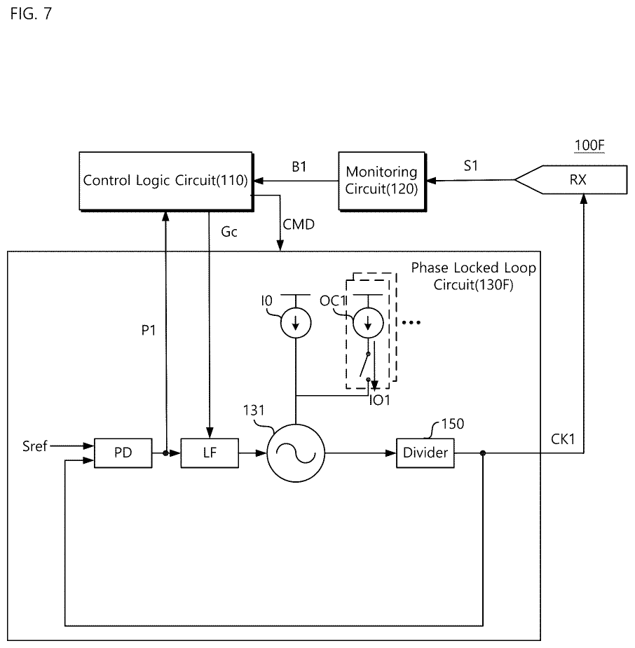

FIG. 7 illustrates an example of a configuration in which a control logic circuit controls a phase locked loop circuit using an over-clock current source and a loop filter.

Referring to FIG. 7, a clock generating device 100F may include the control logic circuit 110, the monitoring circuit 120, and a phase locked loop circuit 130F.

In this case, the clock generating device 100F and the phase locked loop circuit 130F illustrated in FIG. 7 may be understood as examples of the clock generating device 100 and the phase locked loop circuit 130 illustrated in FIG. 1A.

Accordingly, the same reference numeral will be assigned to the same component or substantially the same component as the above-described component, and the duplication thereof will be omitted to avoid redundancy.

In some implementations, the phase locked loop circuit 130F may include the plurality of over-clock current sources OC1 to OCn connected to the oscillator 131. In addition, the phase locked loop circuit 130F may include the divider 150 connected to the output node N1 of the oscillator 131.

In some implementations, the control logic circuit 110 may connect at least some of the plurality of over-clock current sources OC1 to OCn to the oscillator 131, in response to the first bit error rate B1 of the first signal S1 being greater than or equal to the preset threshold value.

For example, the control logic circuit 110 may connect the first over-clock current source OC1 among the plurality of over-clock current sources OC1 to OCn to the oscillator 131, in response to the first bit error rate B1 of the first signal S1 being greater than or equal to the preset threshold value.

The control logic circuit 110 may connect the first over-clock current source OC1 to the oscillator 131 such that the first over-clock current IO1 is additionally applied to the oscillator 131, together with the base current Io, in response to the first bit error rate B1 of the first signal S1 being greater than or equal to the preset threshold value.

In this case, it may be understood that the first over-clock current IO1 has a current amount which is an integer multiple of the base current Io.

Furthermore, the control logic circuit 110 may control the coefficient of the divider 150, in response to the first over-clock current source OC1 being connected to the oscillator 131. In this case, the control logic circuit 110 may control the coefficient of the divider 150 to a value obtained by dividing the current input to the oscillator 131 by the base current Io.

For example, the control logic circuit 110 may control the coefficient of the divider 150 to be ‘3’, in response to the first over-clock current IO1, which is two times the base current Io, being applied to the oscillator 131 through the first over-clock current source OC1.

Meanwhile, when the first bit error rate B1 of the first signal S1 is less than the preset threshold value, the control logic circuit 110 may disconnect at least some of the plurality of over-clock current sources OC1 to OCn from the oscillator 131.

For example, in response to the first bit error rate B1 of the first signal S1 being less than the preset threshold value, the control logic circuit 110 may disconnect the second over-clock current source OC2, which is previously connected to the oscillator 131, among the plurality of over-clock current sources OC1 to OCn, from the oscillator 131. In this case, it is assumed that the second over-clock current source OC2 is previously connected to the oscillator 131.

Furthermore, the control logic circuit 110 may control the coefficient of the divider 150 in response to the disconnection of the second over-clock current source OC2 and the oscillator 131. For example, in response to the disconnection of the second over-clock current source OC2 from the oscillator 131, the coefficient of the divider 150 may be controlled to be ‘1’.

Furthermore, the control logic circuit 110 may control the connection between at least some of the plurality of over-clock current sources OC1 to OCn and the oscillator 131, and then control the gain of the loop filter 142 based on the phase difference P1 between the first clock signal CK1 and the reference signal Sref generated by the oscillator 131.

For example, the control logic circuit 110 may detect the phase difference P1 between the first clock signal CK1 and the reference signal Sref by using the phase detector 141 in the state that at least some of the plurality of over-clock current sources OC1 to OCn are connected to the oscillator 131.

Furthermore, the control logic circuit 110 may control a gain of the loop filter 142 based on the phase difference P1. More specifically, the control logic circuit 110 may generate the gain control signal Gc for controlling a gain (e.g., a proportional gain Kp of FIG. 4B) of the loop filter 142, based on the phase difference P1 between the first clock signal CK1 and the reference signal Sref.

In other words, the control logic circuit 110 may control the gain of the loop filter 142 based on the phase difference P1 between the first clock signal CK1 and the reference signal Sref such that the first bit error rate B1 of the first signal S1 in response to the first clock signal CK1 is decreased after controlling the connection between at least some of the plurality of over-clock current sources OC1 to OCn and the oscillator 131.

Referring to the above-described configuration, the control logic circuit 110 may control the current applied to the oscillator 131 by using at least some of the plurality of over-clock current sources OC1 to OCn based on the first bit error rate B1 of the first signal S1.

Subsequently, the control logic circuit 110 may improve the signal quality of the first signal S1, by controlling the gain of the loop filter 142.

In other words, the clock generating device 100F of the present disclosure may improve the signal quality of the first signal S1 in the state while maintaining power consumption for the phase locked loop circuit 130F after controlling the power applied to the phase locked loop circuit 130F using an over-clock current source.

Accordingly, the clock generating device 100F may minimize an operation of controlling the power applied to the phase locked loop circuit 130F to improve the signal quality of the first signal S1.

In addition, accordingly, the clock generating device 100F may minimize the consumption of power applied to the phase locked loop circuit 130F to improve the signal quality of the first signal S1.

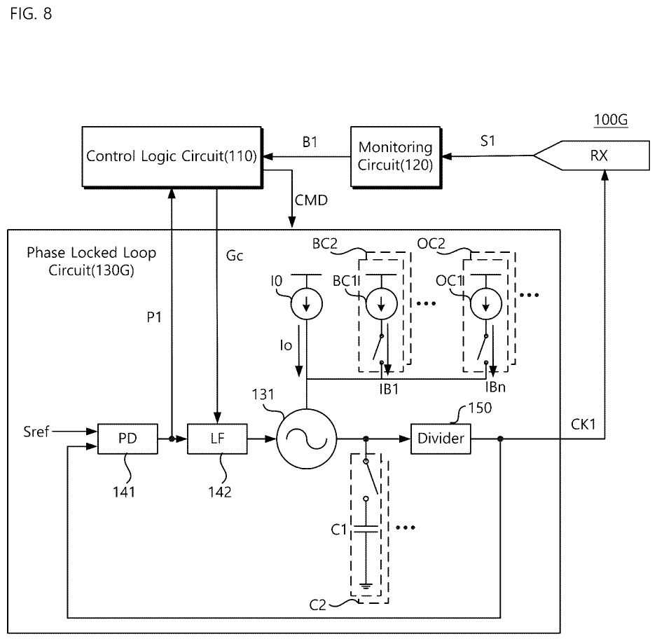

FIG. 8 illustrates an example of a configuration in which a control logic circuit controls a phase locked loop circuit using a boosting current source, an over-clock current source, and a loop filter.

Referring to FIG. 8, a clock generating device 100G may include the control logic circuit 110, the monitoring circuit 120, and a phase locked loop circuit 130G.

In this case, the clock generating device 100G and the phase locked loop circuit 130G illustrated in FIG. 8 may be understood as examples of the clock generating device 100 and the phase locked loop circuit 130 illustrated in FIG. 1A. Accordingly, the same reference numeral will be assigned to the same component or substantially the same component as the above-described component, and the duplication thereof will be omitted to avoid redundancy.

In some implementations, the phase locked loop circuit 130G may include the plurality of boosting current sources BC1 to BCn connected to the oscillator 131. In addition, the phase locked loop circuit 130G may include the plurality of capacitors C1 to Cn connected to the output node N1 of the oscillator 131.

Furthermore, the phase locked loop circuit 130G may include the plurality of over-clock current sources OC1 to OCn connected to the oscillator 131. Furthermore, the phase locked loop circuit 130G may include the divider 150 connected to the output node N1 of the oscillator 131.

In some implementations, the control logic circuit 110 may connect at least some of the plurality of boosting current sources BC1 to BCn to the oscillator 131, in response to the first bit error rate B1 of the first signal S1 being greater than or equal to the preset threshold value.

For example, the control logic circuit 110 may connect the first boosting current source BC1 to the oscillator 131, such that the first boosting current IB1 is additionally applied to the oscillator 131, together with the base current Io, in response to the first bit error rate B1 of the first signal S1 being greater than or equal to the preset threshold value.

In addition, the control logic circuit 110 may connect the first capacitor C1, which corresponds to the first boosting current source BC1, to the output node N1 of the oscillator 131, in response to the first boosting current source BC1 being connected to the oscillator 131.

Furthermore, the control logic circuit 110 may connect at least some of the over-clock current sources OC1 to OCn to the oscillator 131 when the first bit error rate B1 is greater than or equal to a preset threshold value in the state that at least some of the plurality of boosting current sources BC1 to BCn are connected to the oscillator 131.

For example, the control logic circuit 110 may connect at least some of the plurality of over-clock current sources OC1 to OCn to the oscillator 131 when the first bit error rate B1 is greater than or equal to a preset threshold value in the state that the first boosting current source BC1 is connected to the oscillator 131.

For another example, the control logic circuit 110 may connect the first over-clock current source OC1 among the plurality of over-clock current sources OC1 to OCn to the oscillator 131, when the first bit error rate B1 is greater than or equal to the preset threshold value in the state that each of the plurality of boosting current sources BC1 to BCn is connected to the oscillator 131.

In addition, the control logic circuit 110 may control the coefficient of the divider 150 such that the phase locked loop circuit 130G outputs a signal with the same frequency as the first clock signal CK1, in the state that the first over-clock current source OC1 is connected to the oscillator 131.

Through the above-described configurations, the clock generating device 100G may improve the signal quality of the first signal S1 by increasing the current (or power) applied to the phase locked loop circuit 130G, based on the first bit error rate B1 of the first signal S1.

In some implementations, when the first bit error rate B1 of the first signal S1 is less than the preset threshold value, the control logic circuit 110 may disconnect at least some of the plurality of boosting current sources BC1 to BCn from the oscillator 131.

For example, in response to the first bit error rate B1 of the first signal S1 being less than the preset threshold value, the control logic circuit 110 may disconnect the second boosting current source BC2, which is previously connected to the oscillator 131, among the plurality of boosting current sources BC1 to BCn, from the oscillator 131. In this case, it is assumed which the second boosting current source BC2 is previously connected to the oscillator 131.

Furthermore, in response to the disconnection of the second boosting current source BC2 from the oscillator 131, the control logic circuit 110 may disconnect the second capacitor C2 corresponding to the second boosting current source BC2 from the output node N1 of the oscillator 131.

Furthermore, the control logic circuit 110 may disconnect at least some, which have previously connected to the oscillator 131, among the over-clock current sources OC1 to OCn from the oscillator 131 when the first bit error rate B1 is less than the preset threshold value in the state that at least some of the plurality of boosting current sources BC1 to BCn are disconnected from the oscillator 131.

For example, the control logic circuit 110 may disconnect at least some of the plurality of over-clock current sources OC1 to OCn from the oscillator 131 when the first bit error rate B1 is less than the preset threshold value while the first boosting current source BC1 is disconnected from the oscillator 131.

For another example, the control logic circuit 110 may disconnect the second over-clock current source OC2 from the oscillator 131 when the first bit error rate B1 is greater than or equal to the preset threshold value in the state that the plurality of boosting current sources BC1 to BCn are disconnected from the oscillator 131. In this case, it is assumed which the second over-clock current source OC2 is previously connected to the oscillator 131.

In addition, the control logic circuit 110 may control the coefficient of the divider 150 such that the phase locked loop circuit 130G outputs a signal having the same frequency as the first clock signal CK1, in the state that the second over-clock current source OC2 is disconnected from the oscillator 131.

Referring to the above-described configurations, the control logic circuit 110 may increase or decrease the magnitude of the current (or power) applied to the phase locked loop circuit 130G based on the signal quality of the first signal S1 received in response to the first clock signal CK1.

Accordingly, the clock generating device 100G of the present disclosure may improve the power efficiency of an operation for controlling the phase locked loop circuit 130G based on the signal quality of the first signal S1 received in response to the first clock signal CK1.

In addition, referring to the above configurations, the control logic circuit 110 may control the current applied to the oscillator 131 using at least some of the plurality of boosting current sources BC1 to BCn based on the first bit error rate B1 of the first signal S1.

Subsequently, the control logic circuit 110 may control the connection between the plurality of boosting current sources BC1 to BCn and the oscillator 131, and then control the current applied to the oscillator 131 by using at least some of the plurality of over-clock current sources OC1 to OCn based on the first bit error rate B1 of the first signal S1.

Accordingly, the clock generating device 100G of the present disclosure may increase the accuracy of an operation of controlling power for the phase locked loop circuit 130G in response to the first bit error rate B1 of the first signal S1

Furthermore, the control logic circuit 110 may control the connection between the oscillator 131 and at least some of the plurality of boosting current sources BC1 to BCn and the plurality of over-clock current sources OC1 to OCn, and then control the gain of the loop filter 142, based on the phase difference P1 between the first clock signal CK1 generated from the oscillator 131 and the reference signal Sref.

For example, the control logic circuit 110 may sense the phase difference P1 between the first clock signal CK1 and the reference signal Sref by using the phase detector 141, in the state that at least some of the plurality of boosting current sources BC1 to BCn and the plurality of over-clock current sources OC1 to OCn are connected to the oscillator 131.

Furthermore, the control logic circuit 110 may control a gain of the loop filter 142 based on the phase difference P1. More specifically, the control logic circuit 110 may generate the gain control signal Gc for controlling a gain (e.g., a proportional gain Kp of FIG. 4B) of the loop filter 142 based on the phase difference P1 between the first clock signal CK1 and the reference signal Sref.

In other words, the control logic circuit 110 may control the connection between the oscillator 131 and at least some of the plurality of boosting current sources BC1 to BCn and the plurality of over-clock current sources OC1 to OCn, and control the gain of the loop filter 142 based on the phase difference P1 between the first clock signal CK1 and the reference signal Sref such that the first bit error rate B1 of the first signal S1 in response to the first clock signal CK1 is decreased.

Referring to the above-described configuration, the control logic circuit 110 may control the current applied to the oscillator by using at least some of the plurality of boosting current sources BC1 to BCn, based on the first bit error rate B1 of the first signal S1.

Subsequently, the control logic circuit 110 may control the current applied to the oscillator 131 by using at least some of the plurality of over-clock current sources OC1 to OCn, based on the first bit error rate B1 of the first signal S1.

Subsequently, the control logic circuit 110 may improve the signal quality of the first signal S1 by controlling the gain of the loop filter 142.

In other words, the clock generating device 100G of the present disclosure may improve the signal quality of the first signal S1 while maintaining power consumption for the phase locked loop circuit 130G, after controlling the power applied to the phase locked loop circuit 130G using a boosting current source and an over-clock current source.

Accordingly, the clock generating device 100G may minimize an operation for controlling the power applied to the phase locked loop circuit 130G to improve the signal quality of the first signal S1.

In addition, accordingly, the clock generating device 100G may minimize the consumption of power applied to the phase locked loop circuit 130G to improve the signal quality of the first signal S1.

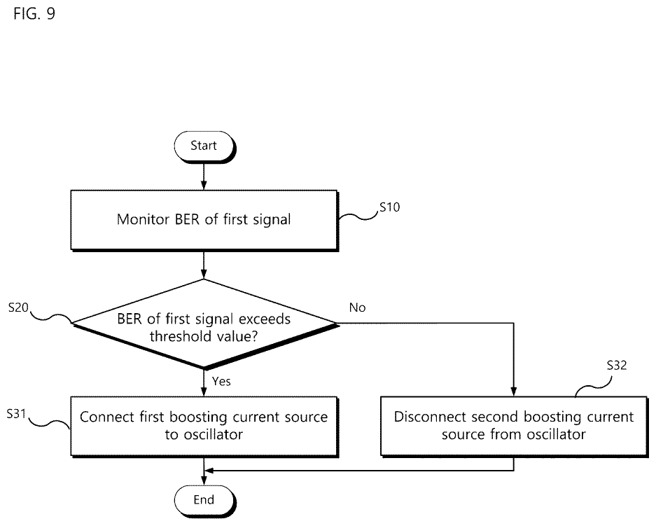

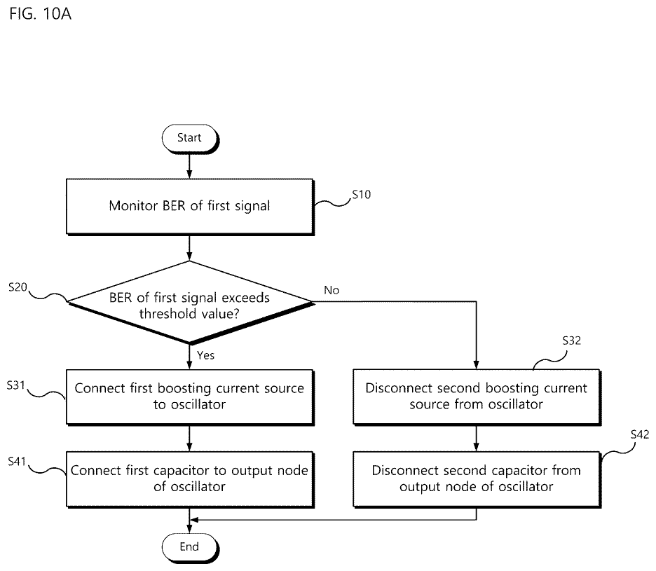

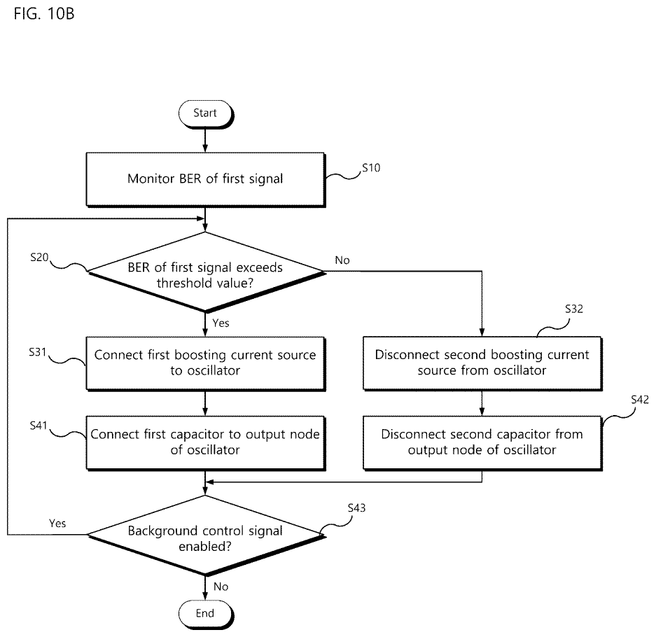

FIG. 9 is a flowchart illustrating an example of a method for controlling a phase locked loop circuit. FIG. 10A is a flowchart illustrating an example of a method for controlling a phase locked loop circuit using a boosting current source. FIG. 10B is a flowchart illustrating an example of a method for controlling a phase locked loop circuit in sequence of the flowchart illustrated in FIG. 10A depending on whether a control logic circuit is operated by background control.

Referring to FIGS. 9, 10A, and 10B together, the clock generating device 100 (or the control logic circuit 110) may control the connection between the current source and the oscillator 131, based on the first bit error rate B1 of the first signal S1.

Accordingly, the control logic circuit 110 may control the power applied to the phase locked loop circuit 130, based on the first bit error rate B1 of the first signal S1.

Referring to FIG. 9, in step S10, the control logic circuit 110 may monitor the first bit error rate B1 of the first signal S1.

More specifically, the control logic circuit 110 may monitor the first bit error rate B1 of the first signal S1 received through the receiver RX, in response to the first clock signal CK1, by using the monitoring circuit 120.

In some implementations, the monitoring circuit 120 may monitor the first bit error rate B1 of the first signal S1, based on the distribution of the first signal S1 received through the receiver RX, in response to the first clock signal CK1.

For example, when the distribution of the first signal S1 is high, the monitoring circuit 120 may determine the first bit error rate B1 of the first signal S1 as being high.

In some implementations, a signal to noise ratio (SNR) of the first signal S1 may be monitored based on the distribution of the first signal S1 received through the receiver RX, in response to the first clock signal CK1.

In this case, for example, it may be understood which the first bit error rate B1 of the first signal S1 is inversely proportional to the SNR.

In other words, the monitoring circuit 120 may monitor (or measure) the signal quality (e.g., bit error rate, SNR) of the first signal S1 received in response to the first clock signal CK1.

In S20, the control logic circuit 110 may determine whether the first bit error rate B1 of the first signal S1 is greater than or equal to the preset threshold value.

More specifically, the control logic circuit 110 may determine whether the first bit error rate B1 of the first signal S1 measured through the monitoring circuit 120 is greater than or equal to the preset threshold value.

In some implementations, the control logic circuit 110 may determine whether the SNR of the first signal S1 measured through the monitoring circuit 120 is less than the preset threshold value.

In this case, for example, the preset threshold value for the bit error rate may be understood as a reference value for determining the possibility of wireless communication using the first signal S1 received through the first clock signal CK1, by the device including the clock generating device 100, but is not limited thereto.

In S31, the control logic circuit 110 may connect the first boosting current source BC1 to the oscillator 131.

More specifically, when the first bit error rate B1 of the first signal S1 is greater than or equal to the preset threshold value, the control logic circuit 110 may connect the first boosting current source BC1 to the oscillator 131.

The control logic circuit 110 may connect the first boosting current source BC1 to the oscillator 131, such that the first boosting current IB1 is applied to the oscillator 131 together with the base current Io, in response to the first bit error rate B1 of the first signal S1 being greater than or equal to the preset threshold value.

To this end, the control logic circuit 110 may turn on a switch interposed between the first boosting current source BC1 and the oscillator 131.

In other words, the control logic circuit 110 may increase the current applied to the oscillator 131, in response to the first bit error rate B1 of the first signal S1 being greater than or equal to the preset threshold value.

Accordingly, the control logic circuit 110 may reduce the first bit error rate B1 of the first signal S1 received in response to the first clock signal CK1 output through the oscillator 131.

Meanwhile, in S32, the control logic circuit 110 may disconnect the second boosting current source BC2, which is previously connected to the oscillator 131, from the oscillator 131. In this case, it is assumed which the second boosting current source BC2 is previously connected to the oscillator 131.

More specifically, the control logic circuit 110 may disconnect the second boosting current source BC2 from the oscillator 131 such that the current applied to the oscillator 131 is decreased, in response to the first bit error rate B1 of the first signal S1 being less than the preset threshold value.

To this end, the control logic circuit 110 may turn off a switch interposed between the oscillator 131 and the second boosting current source BC2 previously connected to the oscillator 131.

In other words, the control logic circuit 110 may reduce the current applied to the oscillator 131, in response to the first bit error rate B1 of the first signal S1 being less than the preset threshold value.

Accordingly, the control logic circuit 110 may minimize the power consumed by the phase locked loop circuit 130 to generate the first clock signal CK1.

Referring to the above-described configurations, the control logic circuit 110 may increase or decrease the magnitude of the current (or power) applied to the phase locked loop circuit 130 based on the signal quality of the first signal S1 received in response to the first clock signal CK1.

Accordingly, the clock generating device 100 of the present disclosure may improve power efficiency for the phase locked loop circuit 130, based on the signal quality of the first signal S1 received in response to the first clock signal CK1.

Referring to FIG. 10A, in S41, the control logic circuit 110 may connect the first capacitor C1 corresponding to the first boosting current source BC1 to the output node N1 of the oscillator 131.

More specifically, the control logic circuit 110 may connect the first capacitor C1 having capacitance corresponding to the first boosting current IB1, to the output node N1 of the oscillator 131, in response to the first boosting current source BC1 being connected to the oscillator 131.

However, as at least some of the plurality of boosting current sources BC1 to BCn are connected to the oscillator 131, the number and configuration of capacitors connected by the control logic circuit 110 to the output node N1 are not limited to the above examples.

In S42, the control logic circuit 110 may disconnect the second capacitor C2 corresponding to the second boosting current source BC2 from the oscillator 131. In this case, it is assumed which the second boosting current source BC2 is previously connected to the oscillator 131.

More specifically, the control logic circuit 110 may disconnect the second capacitor C2 corresponding to the second boosting current source BC2 from the oscillator 131, in response to the disconnection of the second boosting current source BC2 from the oscillator 131.

To this end, the control logic circuit 110 may turn off the switch interposed between the second capacitor C2 and the output node N1 of the oscillator 131.

Referring to the above-described configurations, the control logic circuit 110 may control the connection between the output node N1 of the oscillator 131 and the capacitor in response to a change in the amount of current (or power) applied to the oscillator 131.

Accordingly, the control logic circuit 110 may control the current (or power) for the phase locked loop circuit 130 while maintaining the frequency of the first clock signal CK1 output through the phase locked loop circuit 130.

In addition, referring to FIG. 10B, the control logic circuit 110 may repeatedly perform the operations of S20 to S41, or S20 to S42, in response to the background control signal being activated.

More specifically, the control logic circuit 110 may repeatedly perform the operations of S20 to S41, or S20 to S42, in response to the background control signal being activated, while an electronic device, a semiconductor device, or a semiconductor chip including the clock generating device 100 is operating.

In this case, the background control signal may be understood as a control signal for controlling the signal quality (e.g., bit error rate) of the signal received in response to the clock signal while the electronic device, the semiconductor device, or the semiconductor chip (chip) including the clock generating device 100 is operating.

In S43, the control logic circuit 110 may determine whether the background control signal is activated.

In this case, when the background control signal is activated, the control logic circuit 110 may repeatedly perform the operations of S20 to S41, or S20 to S42.

Meanwhile, when the background control signal is deactivated, the control logic circuit 110 may terminate an operation of controlling the quality of the signal received in response to the clock signal.

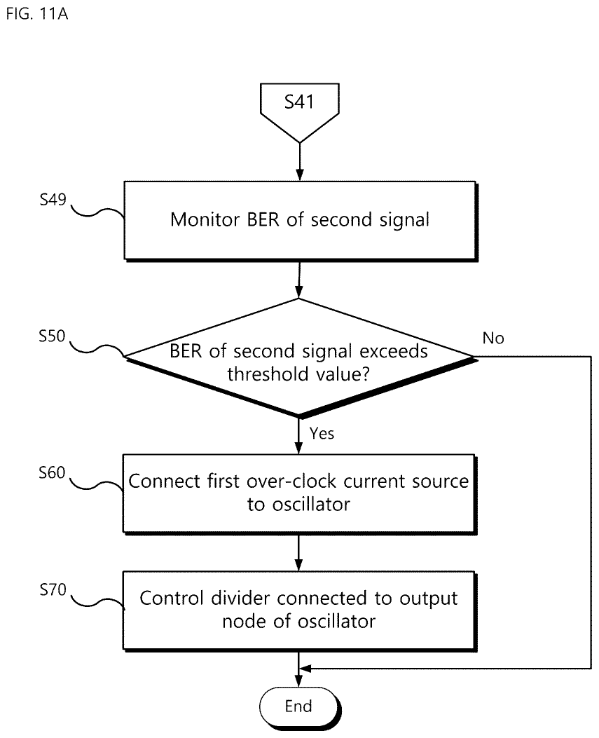

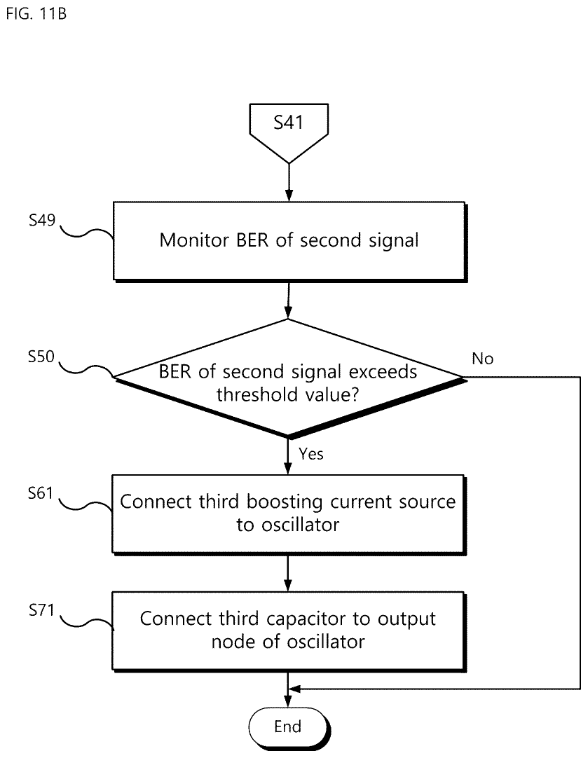

FIG. 11A is a flowchart illustrating an example of a method for controlling a phase locked loop circuit using an over-clock current source. FIG. 11B is a flowchart illustrating an example of a method for controlling a phase locked loop circuit using a boosting current source according to a bit error rate of a second signal.

Referring to FIGS. 11A and 11B together, the control logic circuit 110 may connect the first over-clock current source OC1 to the oscillator 131, based on the second bit error rate B2 of the second signal S2.

More specifically, the control logic circuit 110 may connect the first over-clock current source OC1 to the oscillator 131, based on the second bit error rate of the second signal received in response to the second clock signal output from the oscillator 131, in the state that the first boosting current source BC1 is connected to the oscillator 131.

In S49, the control logic circuit 110 may monitor the second bit error rate of the second signal received in response to the second clock signal output from the oscillator 131, in the state that the first boosting current source BC1 and the first capacitor C1 are connected to the oscillator 131.

In this case, the operation of monitoring the second bit error rate of the second signal by the control logic circuit 110 may be understood as being substantially the same as the operation of monitoring the first bit error rate of the first signal by the control logic circuit 110 in S10 of FIG. 10A.

In S50, the control logic circuit 110 may determine whether the second bit error rate of the second signal is greater than or equal to the preset threshold value.

More specifically, the control logic circuit 110 may determine whether the second bit error rate of the second signal is greater than or equal to the preset threshold value, in the state that the first boosting current source BC1 and the first capacitor C1 are connected to the oscillator 131.

In some implementations, the control logic circuit 110 may determine whether the SNR of the second signal, which is measured in the state that the first boosting current source BC1 and the first capacitor C1 are connected to the oscillator 131, is less than the preset threshold value.

In this case, for example, it may be understood which the operation of S50 is substantially the same as the operation of S20 illustrated in FIG. 9.

In S60, the control logic circuit 110 may connect the first over-clock current source OC1 to the oscillator 131.

More specifically, the control logic circuit 110 may connect the first over-clock current source OC1 to the oscillator 131, when the second bit error rate of the second signal is greater than or equal to the preset threshold value in the state that the first boosting current source BC1 is connected to the oscillator 131.

The control logic circuit 110 may connect the first over-clock current source OC1 to the oscillator 131, such that the first over-clock current source OC1 is applied to the oscillator 131 together with the base current Io, when the second bit error rate of the second signal is greater than or equal to the preset threshold value in the state that the first boosting current source BC1 is connected to the oscillator 131.

To this end, the control logic circuit 110 may turn on a switch interposed between the first over-clock current source OC1 and the oscillator 131.

Referring to the above-described configurations, the control logic circuit 110 may control the current applied to the oscillator 131 using at least some of the plurality of over-clock current sources OC1 to OCn, based on the second bit error rate of the second signal, after controlling the current applied to the oscillator 131 using the first boosting current source BC1.

In this case, for example, it may be understood which the first over-clock current IO1 is greater than the first boost current IB1.

Therefore, through the above-described configurations, the clock generating device 100 of the present disclosure may increase the accuracy of an operation of controlling a current (or power) of the phase locked loop circuit 130 according to the second bit error rate of the second signal. Furthermore, in S70, the control logic circuit 110 may control the divider 150 connected to the output node N1 of the oscillator 131.

More specifically, the control logic circuit 110 may control a coefficient of the divider 150 in response to the first over-clock current source OC1 being connected to the oscillator 131.

For example, in response to the first over-clock current source OC1 being connected to the oscillator 131, the control logic circuit 110 may control the coefficient of the divider 150 to a value obtained by dividing the current input to the oscillator 131 by the base current Io.

In this case, the first over-clock current IO1 may have a current value which is an integer multiple of the base current Io.

Therefore, for example, the control logic circuit 110 may control the coefficient of the divider 150 to be ‘4’, in response to the first over-clock current IO1 having a current value (3*Io), which is three times the base current Io, being applied to the oscillator 131.

Meanwhile, referring to FIG. 11B, in S61, the control logic circuit 110 may connect the third boosting current source BC3 to the oscillator 131.

More specifically, when the second bit error rate of the second signal is greater than or equal to the preset threshold value in the state that the first boosting current source BC1 is connected to the oscillator 131, the control logic circuit 110 may connect the third boosting current source BC3 to the oscillator 131.

When the second bit error rate of the second signal is greater than or equal to the preset threshold value in the state that the first boosting current source BC1 is connected to the oscillator 131, the control logic circuit 110 may connect the third boosting current source BC3 to the oscillator 131, such that the third boosting current IB3 is applied together with the base current Io.

To this end, the control logic circuit 110 may turn on the switch interposed between the third boosting current source BC3 and the oscillator 131.

Referring to the above-described configurations, the control logic circuit 110 may control the current applied to the oscillator 131 using at least some of the plurality of boosting current sources BC3 to BCn, based on the second bit error rate of the second signal, after controlling the current applied to the oscillator 131 using the first boosting current source BC1.

Accordingly, through the above configurations, the clock generating device 100 of the present disclosure may increase the accuracy of the operation of controlling the current (or power) of the phase locked loop circuit 130 according to the second bit error rate of the second signal.

In addition, in S71, the control logic circuit 110 may connect the third capacitor C3 to the oscillator 131.

More specifically, the control logic circuit 110 may connect the third capacitor C3 corresponding to the third boosting current source BC3 to the oscillator 131, in response to the third boosting current source BC3 being connected to the oscillator 131.

To this end, the control logic circuit 110 may turn on the switch interposed between the third capacitor C3 and the oscillator 131.

Referring to the above-described configurations, the control logic circuit 110 may control the coefficient of the divider 150 connected to the output node N1 of the oscillator 131 in response to a change in the amount of current (or power) applied to the oscillator 131.

Accordingly, the control logic circuit 110 may control the current (or power) for the phase locked loop circuit 130, while maintaining the frequency of the first clock signal CK1 output through the phase locked loop circuit 130.

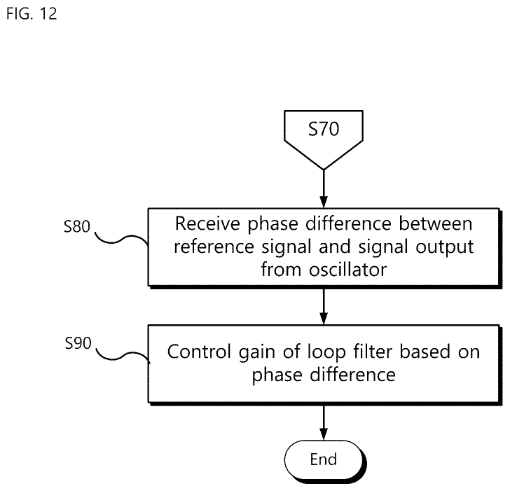

FIG. 12 is a flowchart illustrating an example of a method for controlling a phase locked loop circuit by controlling a gain of a loop filter.

Referring to FIG. 12, the control logic circuit 110 may control the gain of the loop filter 142 based on the phase difference P1 between the first clock signal CK1 and the reference signal Sref.

More specifically, the control logic circuit 110 may control the gain of the loop filter 142, based on the phase difference P1 between the first clock signal CK1 output from the oscillator 131 and the reference signal Sref, in the state that the first boosting current source BC1 and the first over-clock current source OC1 are connected to the oscillator 131.

In S80, the control logic circuit 110 may receive the phase difference P1 between the first clock signal CK1 and the reference signal Sref from the phase detector 141.

More specifically, the control logic circuit 110 may receive the phase difference P1 between the first clock signal CK1 output from the oscillator 131 and the reference signal Sref, in the state that the first boosting current source BC1 and the first over-clock current source OC1 are connected to the oscillator 131.

In S90, the control logic circuit 110 may control the gain of the loop filter 142, based on the phase difference P1.

More specifically, the control logic circuit 110 may control the gain of the loop filter 142, based on the phase difference P1 received in the state that the first boosting current source BC1 and the first over-clock current source OC1 are connected to the oscillator 131.

The control logic circuit 110 may control the gain of the loop filter 142 based on the phase difference P1, such that the first bit error rate B1 of the first signal S1 is decreased, in the state that the first boosting current source BC1 and the first over-clock current source OC1 are connected to the oscillator 131.

Referring to the above configurations, the control logic circuit 110 may improve the signal quality of the first signal S1 while maintaining power consumption for the phase locked loop circuit 130, after controlling the power applied to the phase locked loop circuit 130 using current sources (e.g., the first boosting current source BC1 or the first over-clock current source OC1).

Accordingly, the clock generating device 100 of the present disclosure may minimize an operation of controlling the power applied to the phase locked loop circuit 130 to improve the signal quality of the first signal S1.

In addition, accordingly, the clock generating device 100 may minimize the consumption of power applied to the phase locked loop circuit 130 to improve the signal quality of the first signal S1.

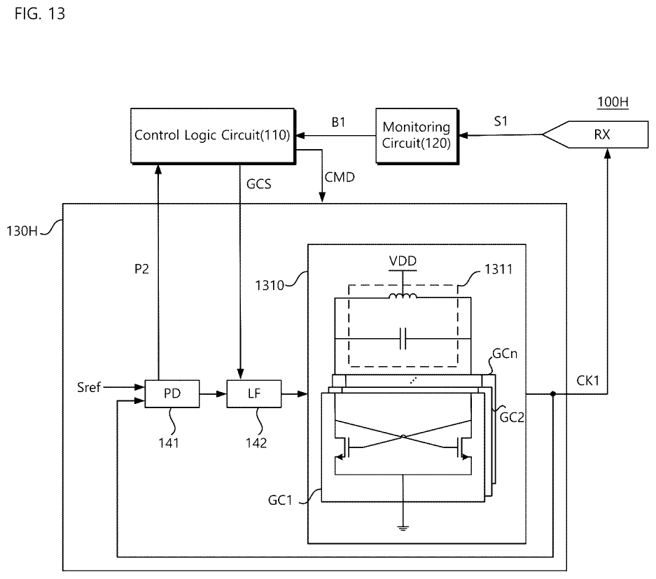

FIG. 13 illustrates an example of a clock generating device including an LC oscillator.

Referring to FIG. 13, a clock generating device 100H may include the control logic circuit 110, the monitoring circuit 120, and a phase locked loop circuit 130H.

In this case, the clock generating device 100H and the phase locked loop circuit 130H illustrated in FIG. 13 may be understood as examples of the clock generating device 100 and the phase locked loop circuit 130 illustrated in FIG. 1A. Accordingly, the same reference numeral will be assigned to the same component or substantially the same component as the above-described component, and the duplication thereof will be omitted to avoid redundancy.

The phase locked loop circuit 130H may include an LC oscillator 1310 which generates the first clock signal CK1 having a specified frequency.

In some implementations, the LC oscillator 1310 may include an inductor-capacitor (LC) tank 1311 including an inductor and a capacitor connected in parallel.

More specifically, the LC oscillator 1310 may include the inductor-capacitor (LC) tank 1311 connected to a power supply voltage VDD and including an inductor and a capacitor connected in parallel.

In addition, the LC oscillator 1310 may include a plurality of cells GC1 to GCn each including a plurality of transistors.

More specifically, the LC oscillator 1310 may the plurality of cells GC1 to GCn connected in parallel to each other and including the plurality of transistors.

In this case, for example, each of the plurality of cells GC1 to GCn included in the LC oscillator 1310 may include two NMOS transistors, but the present disclosure is not limited thereto. In addition, it may be understood that the plurality of cells GC1 to GCn has substantially the same configuration.

In some implementations, at least some of the plurality of cells GC1 to GCn may be connected to the inductor-capacitor tank 1311 to reduce the influence of a parasitic resistor due to the inductor-capacitor tank 1311.

The control logic circuit 110 may control the number of cells connected to the inductor-capacitor tank 1311 based on the first bit error rate B1 of the first signal S1.

More specifically, the control logic circuit 110 may connect or disconnect at least some of the plurality of cells GC1 to GCn to or from the inductor-capacitor tank 1311, based on the first bit error rate B1 of the first signal S1.

In some implementations, the control logic circuit 110 may connect the first cell GC1 to the inductor-capacitor tank 1311 in response to the first bit error rate B1 of the first signal S1 being greater than or equal to the preset threshold value.

Furthermore, the control logic circuit 110 may connect the third cell GC3 to the inductor-capacitor tank 1311 in response to that a second bit error rate of the second signal received in the state that the first cell GC1 is connected to the inductor-capacitor tank 1311 is greater than or equal to the preset threshold value.

Meanwhile, when the first bit error rate B1 of the first signal S1 is less than the preset threshold value, the control logic circuit 110 may disconnect the second cell GC2 previously connected to the inductor-capacitor tank 1311 from the inductor-capacitor tank 1311.

Furthermore, the control logic circuit 110 may control a gain of the loop filter 142, based on a phase difference P2 between the first clock signal CK1 output from the LC oscillator 1310 and the reference signal Sref.

The control logic circuit 110 may generate a gain control signal GCS for controlling the gain of the loop filter 142, based on the phase difference P2 between the first clock signal CK1 output from the LC oscillator 1310 and the reference signal Sref.

More specifically, the control logic circuit 110 may control the connection between at least some of the plurality of cells GC1 to GCn and the inductor-capacitor tank 1311 and then control the gain of the loop filter 142 based on the phase difference P2 between the first clock signal CK1 output from the LC oscillator 1310 and the reference signal Sref.

For example, the control logic circuit 110 may connect the first cell GC1 to the inductor-capacitor tank 1311 and then control the gain of the loop filter 142 such that the first bit error rate B1 of the first signal S1 decreases based on the phase difference P2 between the first clock signal CK1 and the reference signal Sref.

Referring to the above-described configurations, the control logic circuit 110 may increase or decrease the magnitude of the current (or power) applied to the phase locked loop circuit 130H by using the plurality of cells GC1 to GCn included in the LC oscillator 1310 based on the signal quality of the first signal S1 received in response to the first clock signal CK1.

Accordingly, the clock generating device 100H of the present disclosure may improve power efficiency for the phase locked loop circuit 130H, based on the signal quality of the first signal S1 received in response to the first clock signal CK1.

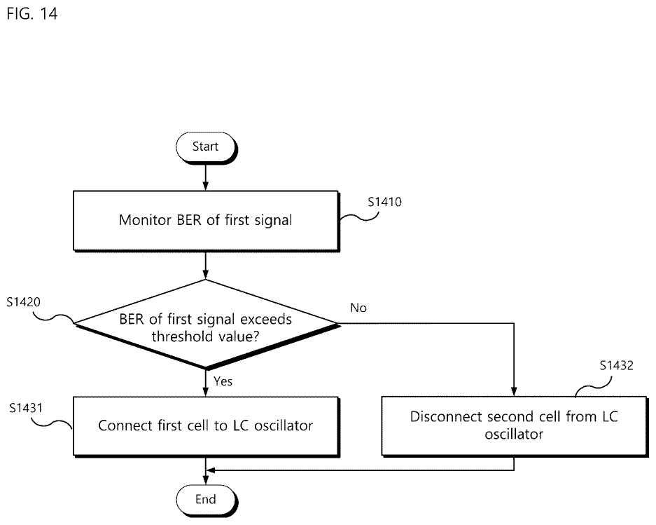

FIG. 14 is a flowchart illustrating an example of a method for controlling the clock generating device of FIG. 13.

Referring to FIG. 14, the clock generating device 100H (or the control logic circuit 110) may control the connection between the cell and the inductor-capacitor tank 1311, based on the first bit error rate B1 of the first signal S1.

Accordingly, the control logic circuit 110 may control the power applied to the phase locked loop circuit 130H, based on the first bit error rate B1 of the first signal S1.

In S1410, the control logic circuit 110 may monitor the first bit error rate B1 of the first signal S1.

More specifically, the control logic circuit 110 may monitor the first bit error rate B1 of the first signal S1 received through the receiver RX in response to the first clock signal CK1 by using the monitoring circuit 120.

In some implementations, the monitoring circuit 120 may monitor the first bit error rate B1 of the first signal S1, based on the distribution of the first signal S1 received through the receiver RX in response to the first clock signal CK1.

For example, when the distribution of the first signal S1 is high, the monitoring circuit 120 may determine the first bit error rate B1 of the first signal S1 as being high.

In some implementations, a signal to noise ratio (SNR) of the first signal S1 may be monitored, based on the distribution of the first signal S1 received through the receiver RX in response to the first clock signal CK1.

In this case, for example, it may be understood that the first bit error rate B1 of the first signal S1 is inversely proportional to the SNR.

In other words, the monitoring circuit 120 may monitor (or measure) the signal quality (e.g., bit error rate, SNR) of the first signal S1 received in response to the first clock signal CK1.

In step S1420, the control logic circuit 110 may determine whether the first bit error rate B1 of the first signal S1 is greater than or equal to the preset threshold value.

More specifically, the control logic circuit 110 may determine whether the first bit error rate B1 of the first signal S1 measured through the monitoring circuit 120 is greater than or equal to the preset threshold value.

In some implementations, the control logic circuit 110 may determine whether the SNR of the first signal S1 measured through the monitoring circuit 120 is less than the preset threshold value.

In this case, for example, the preset threshold value for the bit error rate may be understood as a reference value for determining the possibility of the wireless communication using the first signal S1 received through the first clock signal CK1, by the device including the clock generating device 100H, but the present disclosure is not limited thereto.

In S1431, the control logic circuit 110 may connect the first cell GC1 to the inductor-capacitor tank 1311.

More specifically, when the first bit error rate B1 of the first signal S1 is greater than or equal to the preset threshold value, the control logic circuit 110 may connect the first cell GC1 to the inductor-capacitor tank 1311.

The control logic circuit 110 may connect the first cell GC1 to the inductor-capacitor tank 1311 such that the effect of the parasitic resistance due to the inductor-capacitor tank 1311 is cancelled, in response to the first bit error rate B1 of the first signal S1 being greater than or equal to the preset threshold value.

Accordingly, the control logic circuit 110 may reduce the first bit error rate B1 of the first signal S1 received in response to the first clock signal CK1 output through the LC oscillator 1310.

Meanwhile, in step S1432, the control logic circuit 110 may disconnect the second cell GC2 previously connected to the inductor-capacitor tank 1311 from the inductor-capacitor tank 1311.

More specifically, the control logic circuit 110 may disconnect the second cell GC2 from the inductor-capacitor tank 1311 such that the power applied to the phase locked loop circuit 130H is reduced, in response to the first bit error rate B1 of the first signal S1 being less than the preset threshold value.

Accordingly, the control logic circuit 110 may minimize the power consumed by the phase locked loop circuit 130H to generate the first clock signal CK1.

Referring to the above-described configurations, the control logic circuit 110 may increase or decrease the magnitude of the power applied to the phase locked loop circuit 130H based on the signal quality of the first signal S1 received in response to the first clock signal CK1.

Accordingly, the clock generating device 100H of the present disclosure may improve power efficiency for the phase locked loop circuit 130H based on the signal quality of the first signal S1 received in response to the first clock signal CK1.

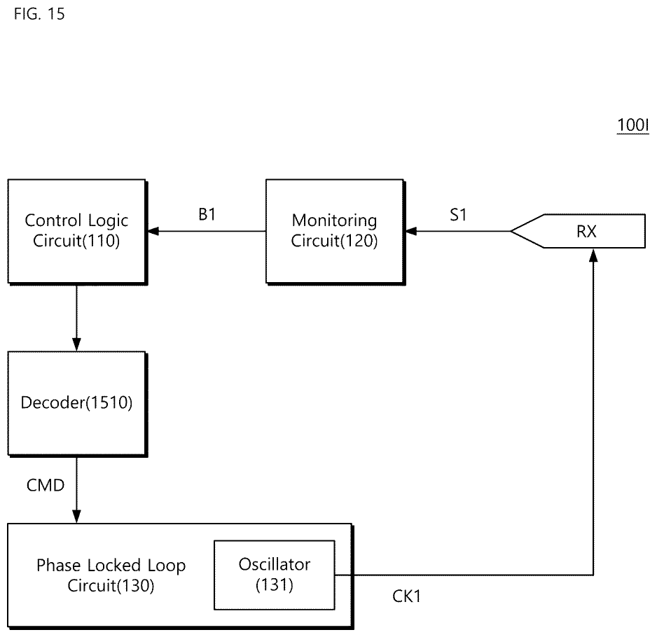

FIG. 15 is a block diagram illustrating an example of a clock generating device further including a decoder.

Referring to FIG. 15, a clock generating device 100I may include the control logic circuit 110, the monitoring circuit 120, a decoder 1510, and the phase locked loop circuit 130.

In this case, the clock generating device 100I illustrated in FIG. 15 may be understood as an example of the clock generating device 100 illustrated in FIG. 1A. Accordingly, the same reference numeral will be assigned to the same component or substantially the same component as the above-described component, and the duplication thereof will be omitted to avoid redundancy.

The clock generating device 100I may further include the decoder 1510 coupled to the control logic circuit 110.

In some implementations, the decoder 1510 may include a lookup table (LUT) including a bit error rate of a signal received from the monitoring circuit 120 and a control signal corresponding to the bit error rate.

In some implementations, after providing the control signal to the phase locked loop circuit 130, the control logic circuit 110 may store the bit error rate of the received signal and the provided control signal, in the lookup table.

In this case, the control logic circuit 110 may store the control signal according to each bit error rate and bit error rate in the lookup table such that there is linearity between the control signal and the bit error rate.

In some implementations, when the first bit error rate B1 of the first signal S1 is greater than or equal to the preset threshold value, the control logic circuit 110 may output the control signal for increasing the amount of power applied to the phase locked loop circuit 130 using the lookup table.

Accordingly, the control logic circuit 110 may increase the amount of power applied to the phase locked loop circuit 130.

In some implementations, when the first bit error rate B1 of the first signal S1 is less than the preset threshold value, the control logic circuit 110 may output the control signal for reducing the amount of power applied to the phase locked loop circuit 130 using the lookup table.

Accordingly, the control logic circuit 110 may reduce the amount of power applied to the phase locked loop circuit 130.

Referring to the above-described configurations, the control logic circuit 110 may output a control signal corresponding to a bit error rate of a received signal using a pre-stored lookup table.

Accordingly, the control logic circuit 110 may control power (or current) applied to the phase locked loop circuit 130.

Accordingly, the clock generating device 100I according to the present disclosure may reduce the power and cost required to generate a control signal for controlling the phase locked loop circuit 130, depending on the bit error rate of the received signal.

As described above, the control logic circuit 110 of the present disclosure may increase the current applied to the oscillator 131, in response to the first bit error rate B1 of the first signal S1 being greater than or equal to the preset threshold value.

Accordingly, the control logic circuit 110 may reduce the first bit error rate B1 of the first signal S1 received in response to the first clock signal CK1 output through the oscillator 131.

In addition, the control logic circuit 110 may reduce the current applied to the oscillator 131, in response to the first bit error rate B1 of the first signal S1 being less than a preset threshold value.

Accordingly, the clock generating device 100 of the present disclosure may minimize the power consumed by the phase locked loop circuit 130 to generate the first clock signal CK1.

In addition, the control logic circuit 110 may control a capacitor or a divider connected to the output node N1 of the oscillator 131 while controlling the current applied to the oscillator 131 based on the first bit error rate B1 of the first signal S1.

Accordingly, the clock generating device 100 of the present disclosure may maintain the frequency of the first clock signal CK1 output through the phase locked loop circuit 130.

In addition, the control logic circuit 110 may increase or decrease the magnitude of the current (or power) applied to the phase locked loop circuit 130 based on the signal quality of the first signal S1 (e.g., the first bit error rate (B1)) received in response to the first clock signal CK1.

Accordingly, the clock generating device 100 of the present disclosure may improve power efficiency for the phase locked loop circuit 130, based on the signal quality of the first signal S1 received in response to the first clock signal CK1.

In addition, the control logic circuit 110 may control the signal quality of the first signal S1 received in response to the first clock signal CK1 by controlling the boosting current source and the over-clock current source in a preset order.

The clock generating device 100 of the present disclosure may minimize an operation of controlling power applied to the phase locked loop circuit 130 to improve the signal quality of the first signal S1.

In addition, accordingly, the clock generating device 100 may minimize the consumption of power applied to the phase locked loop circuit 130 to improve the signal quality of the first signal S1.

In some implementations of the present disclosure, an apparatus for generating a clock may be provided to control power applied to a phase locked loop circuit based on signal quality of a signal received in response to a clock signal.

Accordingly, according to the apparatus for generating a clock of the present disclosure, the power efficiency of the phase locked loop circuit may be improved.

In addition to the above implementations, a simple design modification or an easy change of the implementations will fall within the scope of the present disclosure. In addition, technologies easily modified using implementations of the present disclosure will fall within the scope of the present disclosure. Accordingly, the scope of the present disclosure is not limited to the above implementations, but defined through equivalents of following claims as well as the following claims.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that modifications, and changes may be made thereto without departing from the spirit and scope of the present disclosure as set forth in the following claims.

What is claimed is:

1. An apparatus for generating a clock, the apparatus comprising:
a phase locked loop circuit configured to generate, through an oscillator, a first clock signal having a specified frequency;
a monitoring circuit configured to monitor a first bit error rate of a first signal received based on the first clock signal, thereby generating a monitoring result; and
a control logic circuit configured to control the phase locked loop circuit based on the monitoring result,
wherein the control logic circuit is configured to:
based on the first bit error rate being equal to or greater than a threshold value, connect a first boosting current source with the oscillator, wherein the first boosting current source is included in the phase locked loop circuit, and
based on the first bit error rate being less than the threshold value, disconnect a second boosting current source from the oscillator, wherein the second boosting current source is previously connected with the oscillator.

2. The apparatus of claim 1, wherein the phase locked loop circuit includes:
a plurality of boosting current sources including the first boosting current source, and
a plurality of capacitors corresponding to the plurality of boosting current sources, and
wherein the control logic circuit is configured to:
based on the first boosting current source being connected with the oscillator, connect a first capacitor corresponding to the first boosting current source with an output node of the oscillator.

3. The apparatus of claim 2, wherein the phase locked loop circuit includes:
a divider connected with the output node of the oscillator, and
wherein the control logic circuit is configured to:
based on the first bit error rate being equal to or greater than the threshold value, connect a first over-clock current source with the oscillator, wherein the first over-clock current source is separate from the first boosting current source; and
control a coefficient of the divider such that the phase locked loop circuit is configured to output a signal in a state that the first over-clock current source is connected with the oscillator, the signal having the specified frequency.

4. The apparatus of claim 3, wherein the phase locked loop circuit includes a basic current source configured to provide a base current to the oscillator,
wherein the first over-clock current source has a current amount being an integer multiple of the base current, and
wherein the control logic circuit is configured to, based on the first over-clock current source being connected with the oscillator, control a coefficient of the divider, the coefficient having a value obtained by dividing a current by the base current, wherein the current is applied to the oscillator.

5. The apparatus of claim 1, wherein the phase locked loop circuit includes:
a phase detector configured to output a phase difference between the first clock signal and a reference signal, and
a loop filter configured to control the oscillator based on the phase difference, and
wherein the control logic circuit is configured to control a gain of the loop filter such that the first bit error rate decreases based on the phase difference.

6. The apparatus of claim 2, wherein the control logic circuit is configured to:
based on the second boosting current source being disconnected from the oscillator, disconnect, from the output node of the oscillator, a second capacitor corresponding to the second boosting current source among the plurality of capacitors.

7. The apparatus of claim 3, wherein the control logic circuit is configured to:
based on the first bit error rate being less than the threshold value, disconnect a second over-clock current source from the oscillator, and
control the coefficient of the divider such that the phase locked loop circuit is configured to output a signal in a state that the second over-clock current source is disconnected from the oscillator, the signal having the specified frequency.

8. The apparatus of claim 2, wherein the monitoring circuit is configured to monitor a second bit error rate of a second signal received based on a second clock signal output from the phase locked loop circuit, wherein the second clock signal is output from the phase locked loop circuit in a state that the first boosting current source and the first capacitor are connected with the oscillator, and
wherein the control logic circuit is configured to, based on the second bit error rate being equal to or greater than the threshold value,
connect a third boosting current source with the oscillator, wherein the third boosting current source is connected with the first boosting current source in parallel, and
connect a third capacitor corresponding to the third boosting current source with the output node of the oscillator.

9. The apparatus of claim 3, wherein the first over-clock current source is configured to output a first over-clock current, the first over-clock current being greater than a first boosting current of the first boosting current source.

10. The apparatus of claim 1, comprising:
a decoder including a look-up table, the look-up table containing a bit error rate of a signal and a control signal corresponding to the bit error rate, the signal being received in a clock signal, and
wherein the control logic circuit is configured to transmit a control signal to the phase locked loop circuit based on the look-up table, and the control signal corresponds to a bit error rate of the first signal received from the monitoring circuit.

11. A method for generating a clock, the method comprising:
monitoring a first bit error rate of a first signal received based on a first clock signal, the first clock signal having a specified frequency;
based on the first bit error rate being equal to or greater than a threshold value, connecting a first boosting current source with an oscillator, the first boosting current source being included in a phase locked loop circuit; and
based on the first bit error rate being less than the threshold value, disconnecting a second boosting current source from the oscillator, wherein the second boosting current source is previously connected with the oscillator.

12. The method of claim 11, wherein the phase locked loop circuit includes a plurality of capacitors corresponding to a plurality of boosting current sources, the plurality of boosting current sources including the first boosting current source and the second boosting current source, and
wherein the method includes:
based on the first boosting current source being connected to the oscillator, connecting a first capacitor among the plurality of capacitors with an output node of the oscillator, wherein the first capacitor corresponds to the first boosting current source.

13. The method of claim 12, comprising:
based on a second bit error rate of a second signal received in a second clock signal output from the oscillator being equal to or greater than the threshold value, connecting a first over-clock current source with the oscillator, wherein the first over-clock current source is separate from the first boosting current source, and the second clock signal is output from the oscillator in a state that the first boosting current source and the first capacitor are connected with the oscillator, and
controlling a coefficient of a divider connected to the output node such that the phase locked loop circuit is configured to output a signal in a state that the first over-clock current source is connected with the oscillator, the signal having the specified frequency.

14. The method of claim 13, comprising:
receiving a phase difference between the second clock signal output from the oscillator and a reference signal, the phase difference being received in a state that the first boosting current source and the first over-clock current source are connected with the oscillator; and
controlling a gain of a loop filter included in the phase locked loop circuit, wherein controlling the gain decrease the first bit error rate based on the phase difference.

15. The method of claim 12, comprising:
based on the second boosting current source being disconnected from the oscillator, disconnecting a second capacitor among the plurality of capacitors from the output node, wherein the second capacitor corresponds to the second boosting current source.

16. An apparatus for generating a clock, the apparatus comprising:
a phase locked loop circuit configured to generate, through an inductor-capacitor oscillator, a first clock signal having a specified frequency;
a monitoring circuit configured to monitor a first bit error rate of a first signal received based on the first clock signal, thereby generating a monitoring result; and
a control logic circuit configured to control the phase locked loop circuit based on the monitoring result,
wherein the inductor-capacitor oscillator includes:
an inductor-capacitor tank in which an inductor and a capacitor are connected in parallel, and
a plurality of cells, each cell of the plurality of cells including a plurality of transistors, the plurality of cells being connected with each other in parallel, and
wherein the control logic circuit is configured to, based on the first bit error rate being equal to or greater than a threshold value, connect a first cell from the plurality of cells with the inductor-capacitor tank.

17. The apparatus of claim 16, wherein the control logic circuit is configured to, based on the first bit error rate being less than the threshold value, disconnect a second cell from the inductor-capacitor tank.

18. The apparatus of claim 16, wherein the phase locked loop circuit includes:
a phase detector configured to output a phase difference between the first clock signal and a reference signal, the first clock signal being output from the inductor-capacitor oscillator, and
a loop filter configured to control the inductor-capacitor oscillator based on the phase difference, and
wherein the control logic circuit is configured to, based on the first cell being connected with the inductor-capacitor tank, control a gain of the loop filter such that the first bit error rate is decreased based on the phase difference.

19. The apparatus of claim 16, comprising:
a decoder including a look-up table, the look-up table containing a bit error rate of a received signal and a control signal corresponding to the bit error rate, and
wherein the control logic circuit is configured to transmit a control signal to the phase locked loop circuit based on the look-up table, and the control signal corresponds to the first bit error rate received from the monitoring circuit.

20. The apparatus of claim 16, wherein the monitoring circuit is configured to monitor a second bit error rate of a second signal received based on a second clock signal output from the phase locked loop circuit, the second clock signal being output from the phase locked loop circuit in a state that the first cell is connected with the inductor-capacitor tank, and
wherein the control logic circuit is configured to, based on the second bit error rate being equal to or greater than the threshold value, connect a third cell with the inductor-capacitor tank, and the third cell is connected with the first cell in parallel.
